(19) United States
(12) Patent Application Publication
(10) Pub. No.: US 2006/0285375 A1
(43) Pub. Date: Dec. 21, 2006

(54) Semiconductor memory and method for manufacturing the semiconductor memory

(75) Inventors: Masato Endo, Kanagawa (JP); Atsuhiro Sato, Kanagawa (JP); Fumitaka Arai, Kanagawa (JP); Tooru Maruyama, Mie (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/342,533

(22) Filed: Jan. 31, 2006

(30) Foreign Application Priority Data
Jun. 16, 2005 (JP) 2005-176904

(51) Int. Cl. G11C 5/06

(52) U.S. Cl. 365/63

(57) ABSTRACT

A semiconductor memory includes a semiconductor region, floating gate electrodes arranged in a matrix on the semiconductor region through a tunnel insulating layer, inter-gate insulating layers disposed only on the plurality of floating gate electrodes, respectively, control gate electrodes disposed on the plurality of inter-gate insulating layers, respectively, and isolation insulators extending between arrangements of the control gate electrodes along a column direction of the matrix, each of the isolation insulators penetrating into the semiconductor region so as to electrically isolate the inter-gate insulating layers from each other in the column direction.

### CROSS REFERENCE TO RELATED APPLICATIONS AND INCORPORATION BY REFERENCE

This application is based upon and claims the benefit of priority from prior Japanese Patent Application P2005-176904 filed on Jun. 16, 2005; the entire contents of which are incorporated by reference herein.

### BACKGROUND OF THE INVENTION

1. Field of the Invention

The present invention relates to a semiconductor memory and a method for manufacturing the semiconductor memory and in particular to a nonvolatile memory cell.

2. Description of the Related Art

An electrically erasable programmable read-only memory (EEPROM) is widely used as a nonvolatile memory cell. The EEPROM generally has an electrically trimmable threshold voltage. The EEPROM includes a plurality of memory cell transistors. Each of the memory cell transistors includes a floating gate electrode surrounded by an insulating layer to retain a plurality of charges for a long time. The memory cell transistor further includes a control gate electrode configured to inject electrons into the floating gate electrode. The control gate electrode is disposed above the floating gate electrode. Also, an inter-gate insulating layer is disposed between the floating gate electrode and the control gate electrode. In an earlier EEPROM, as described in Japanese Patent Laid-Open Publication No. 2003-60092, the plurality of memory cell transistors are commonly covered by the contiguous inter-gate insulating layer covering all of the floating gate electrodes. However, if a charge trap level is located in the contiguous inter-gate insulating layer, the plurality of charges move among the plurality of floating gate electrodes through the contiguous inter-gate insulating layer.

### SUMMARY OF THE INVENTION

An aspect of present invention inheres in a semiconductor memory according to an embodiment of the present invention. The semiconductor memory includes a plurality of floating gate electrodes arranged in a matrix on the semiconductor region through a tunnel insulating layer and a plurality of inter-gate insulating layers disposed only on the plurality of floating gate electrodes, respectively. A plurality of control gate electrodes are disposed on the plurality of inter-gate insulating layers, respectively. A plurality of isolation insulators extend between a plurality of arrangements of the control gate electrodes along a column direction of the matrix. Each of the isolation insulators penetrates into the semiconductor region so as to electrically isolate the plurality of inter-gate insulating layers from each other in the column direction.

Another aspect of the present invention inheres in a method for manufacturing the semiconductor memory according to the embodiment of the present invention. The method for manufacturing the semiconductor memory includes forming a tunnel insulating layer on a semiconductor region, depositing a first conducting layer on the tunnel insulating layer, forming an interlayer insulator on the first conducting layer, and depositing a second conducting layer on the interlayer insulator. The method further includes delineating a plurality of column isolation trenches penetrating from the second conducting layer to an interior of the semiconductor region. The column isolation trenches extend in a column direction so as to divide the second conducting layer, the interlayer insulator, and the first conducting layer into a plurality of strips of the second conducting layers, the interlayer insulators, and the first conducting layers, respectively. The method further includes filling the column isolation trenches with a plurality of isolation insulators so that the plurality of strips of the interlayer insulators are isolated from each other in the column direction by the isolation insulators. The method further includes dividing the stripes of the first conducting layers, the interlayer insulators, and the second conducting layers by a plurality of row isolation trenches running along a row direction perpendicular to the column direction to form a plurality of floating gate electrodes on the tunnel insulating layer, a plurality of inter-gate insulating layers on the plurality of floating gate electrodes, and a plurality of control gate electrodes on the plurality of inter-gate insulating layers, respectively.

### BRIEF DESCRIPTION OF DRAWINGS

FIG. 1 is a top view of a semiconductor memory in accordance with an embodiment of the present invention;

FIG. 2 is a schematic drawing of the semiconductor memory in accordance with the embodiment of the present invention;

FIG. 3 is a cross sectional view of the semiconductor memory shown in FIG. 1 cut from a direction of line III-III in accordance with the embodiment of the present invention;

FIG. 4 is a cross sectional view of the semiconductor memory shown in FIG. 1 cut from a direction of line IV-IV in accordance with the embodiment of the present invention;

FIG. 5 is a cross sectional view of a semiconductor memory according to a comparative example;

FIG. 6 is a first plane view of the semiconductor memory depicting a manufacturing process in accordance with the embodiment of the present invention;

FIG. 7 is a first sectional view of the semiconductor memory shown in FIG. 6 cut from a direction of line VII-VII depicting the manufacturing process in accordance with the embodiment of the present invention;

FIG. 8 is a second sectional view of the semiconductor memory shown in FIG. 6 cut from a direction of line VII-VII depicting the manufacturing process in accordance with the embodiment of the present invention;

FIG. 9 is a second plane view of the semiconductor memory depicting the manufacturing process in accordance with the embodiment of the present invention;

FIG. 10 is a sectional view of the semiconductor memory shown in FIG. 9 cut from a direction of line X-X depicting the manufacturing process in accordance with the embodiment of the present invention;

FIG. 11 is a third plane view of the semiconductor memory depicting the manufacturing process in accordance with the embodiment of the present invention;

FIG. 12 is a first sectional view of the semiconductor memory shown in FIG. 11 cut from a direction of line XII-XII depicting the manufacturing process in accordance with the embodiment of the present invention;

FIG. 13 is a second sectional view of the semiconductor memory shown in FIG. 11 cut from a direction of line XII-XII depicting the manufacturing process in accordance with a modification of the embodiment of the present invention;

FIG. 14 is a fourth plane view of the semiconductor memory depicting the manufacturing process in accordance with the embodiment of the present invention;

FIG. 15 is a sectional view of the semiconductor memory shown in FIG. 14 cut from a direction of line XV-XV depicting the manufacturing process in accordance with the embodiment of the present invention;

FIG. 16 is a fifth plane view of the semiconductor memory depicting the manufacturing process in accordance with the embodiment of the present invention;

FIG. 17 is a first sectional view of the semiconductor memory shown in FIG. 16 cut from a direction of line XVII-XVII depicting the manufacturing process in accordance with the embodiment of the present invention;

FIG. 18 is a second sectional view of the semiconductor memory shown in FIG. 16 cut from a direction of line XVIII-XVIII depicting the manufacturing process in accordance with the embodiment of the present invention;

FIG. 19 is a third sectional view of the semiconductor memory shown in FIG. 16 cut from a direction of line XVIII-XVIII depicting the manufacturing process in accordance with the modification of the embodiment of the present invention;

FIG. 20 is a sixth plane view of the semiconductor memory depicting the manufacturing process in accordance with the embodiment of the present invention;

FIG. 21 is a sectional view of the semiconductor memory shown in FIG. 20 cut from a direction of line XXI-XXI depicting the manufacturing process in accordance with the embodiment of the present invention;

FIG. 22 is a seventh plane view of the semiconductor memory depicting the manufacturing process in accordance with the embodiment of the present invention;

FIG. 23 is a sectional view of the semiconductor memory shown in FIG. 22 cut from a direction of line XXIII-XXIII depicting the manufacturing process in accordance with the embodiment of the present invention;

FIG. 24 is an eighth plane view of the semiconductor memory depicting the manufacturing process in accordance with the embodiment of the present invention;

FIG. 25 is a sectional view of the semiconductor memory shown in FIG. 24 cut from a direction of line XXV-XXV depicting the manufacturing process in accordance with the embodiment of the present invention;

FIG. 26 is a ninth plane view of the semiconductor memory depicting the manufacturing process in accordance with the embodiment of the present invention;

FIG. 27 is a sectional view of the semiconductor memory shown in FIG. 26 cut from a direction of line XXVII-XXVII depicting the manufacturing process in accordance with the embodiment of the present invention;

FIG. 28 is a tenth plane view of the semiconductor memory depicting the manufacturing process in accordance with the embodiment of the present invention;

FIG. 29 is a first sectional view of the semiconductor memory shown in FIG. 28 cut from a direction of line XXIX-XXIX depicting the manufacturing process in accordance with the embodiment of the present invention;

FIG. 30 is a second sectional view of the semiconductor memory shown in FIG. 28 cut from a direction of line XXIX-XXIX depicting the manufacturing process in accordance with the embodiment of the present invention;

FIG. 31 is a third sectional view of the semiconductor memory shown in FIG. 28 cut from a direction of line XXIX-XXIX depicting the manufacturing process in accordance with the embodiment of the present invention;

FIG. 32 is a fourth sectional view of the semiconductor memory shown in FIG. 28 cut from a direction of line XXIX-XXIX depicting the manufacturing process in accordance with the modification of the embodiment of the present invention;

FIG. 33 is an eleventh plane view of the semiconductor memory depicting the manufacturing process in accordance with the embodiment of the present invention;

FIG. 34 is a first sectional view of the semiconductor memory shown in FIG. 33 cut from a direction of line XXXIV-XXXIV depicting the manufacturing process in accordance with the embodiment of the present invention;

FIG. 35 is a second sectional view of the semiconductor memory shown in FIG. 33 cut from a direction of line XXXV-XXXV depicting the manufacturing process in accordance with the embodiment of the present invention;

FIG. 36 is a twelfth plane view of the semiconductor memory depicting the manufacturing process in accordance with the embodiment of the present invention;

FIG. 37 is a first sectional view of the semiconductor memory shown in FIG. 36 cut from a direction of line XXXVII-XXXVII depicting the manufacturing process in accordance with the embodiment of the present invention;

FIG. 38 is a second sectional view of the semiconductor memory shown in FIG. 36 cut from a direction of line XXXVIII-XXXVIII depicting the manufacturing process in accordance with the embodiment of the present invention;

FIG. 39 is a third sectional view of the semiconductor memory shown in FIG. 36 cut from a direction of line XXXVII-XXXVII depicting the manufacturing process in accordance with the embodiment of the present invention; and

FIG. 40 is a fourth sectional view of the semiconductor memory shown in FIG. 36 cut from a direction of line XXXVII-XXXVII depicting the manufacturing process in accordance with the embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

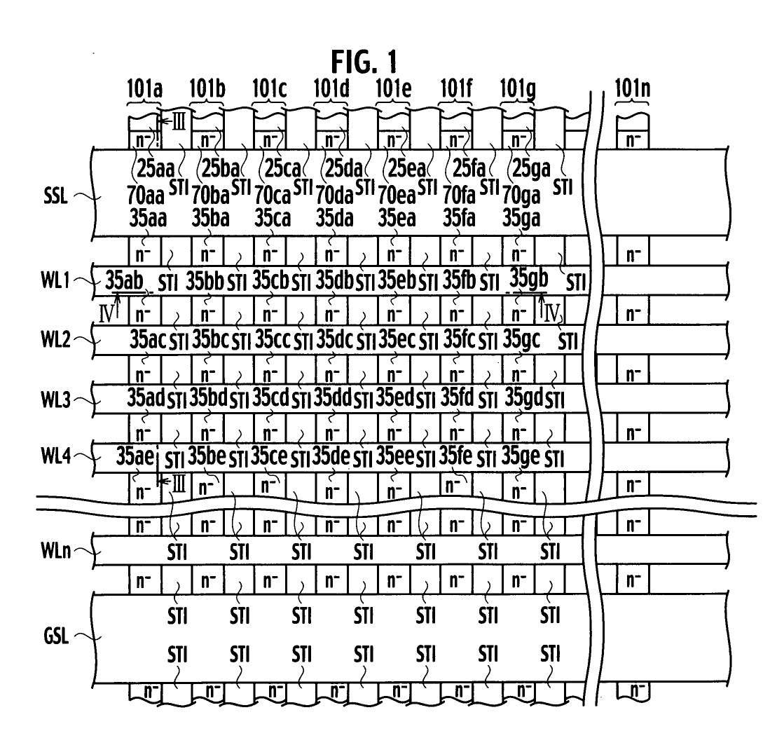

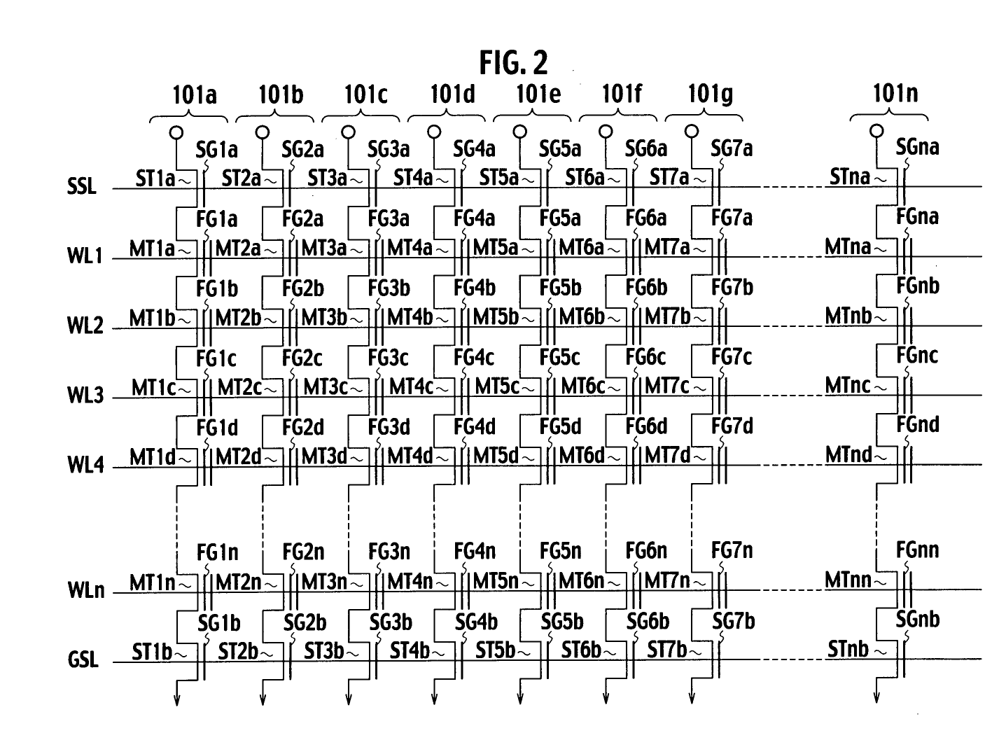

With reference to FIG. 1, in a semiconductor memory according to the embodiment, a first column 101a, a second column 101b, a third column 101c, a fourth column 101c, a fifth column 101e, a sixth column 101f, a seventh column 101g, and an n-th column 101n, arranged in an array, are defined. A circuit diagram of the semiconductor memory is shown in FIG. 2. In the first column 101a, a select gate transistor ST1a including a select gate electrode SG1a is disposed. A plurality of memory cell transistors MT1a, MT1b, MT1c, MT1d, . . . , and MT1n are serially connected to the select gate transistor ST1a. The plurality of memory cell transistors MT1a, MT1b, MT1c, MT1d, . . . , and MT1n include a plurality of floating gate electrodes FG1a, FG1b, FG1c, FG1d, . . . , and FG1n, respectively. A select gate transistor ST1b including a select gate electrode SG1b is serially connected to the memory cell transistor MT1n.

In the second column 101b, a select gate transistor ST2a including a select gate electrode SG2a is disposed. A plurality of memory cell transistors MT2a, MT2b, MT2c, MT2d, . . . , and MT2n are serially connected to the select gate transistor ST2a. The plurality of memory cell transistors MT2a, MT2b, MT2c, MT2d, . . . , and MT2n include a plurality of floating gate electrodes FG2a, FG2b, FG2c, FG2d, . . . , and FG2n, respectively. A select gate transistor ST2b including a select gate electrode SG2b is serially connected to the memory cell transistor MT2n.

In the third column 101c, a select gate transistor ST3a including a select gate electrode SG3a is disposed. A plurality of memory cell transistors MT3a, MT3b, MT3c, MT3d, . . . , and MT3n are serially connected to the select gate transistor ST3a. The plurality of memory cell transistors MT3a, MT3b, MT3c, MT3d, . . . , and MT3n include a plurality of floating gate electrodes FG3a, FG3b, FG3c, FG3d, . . . , and FG3n, respectively. A select gate transistor ST3b including a select gate electrode SG3b is serially connected to the memory cell transistor MT3n.

In the fourth column 101d, a select gate transistor ST4a including a select gate electrode SG4a is disposed. A plurality of memory cell transistors MT4a, MT4b, MT4c, MT4d, . . . , and MT4n are serially connected to the select gate transistor ST4a. The plurality of memory cell transistors MT4a, MT4b, MT4c, MT4d, . . . , and MT4n include a plurality of floating gate electrodes FG4a, FG4b, FG4c, FG4d, . . . , and FG4n, respectively. A select gate transistor ST4b including a select gate electrode SG4b is serially connected to the memory cell transistor MT4n.

In the fifth column 101e, a select gate transistor ST5a including a select gate electrode SG5a is disposed. A plurality of memory cell transistors MT5a, MT5b, MT5c, MT5d, . . . , and MT5n are serially connected to the select gate transistor ST5a. The plurality of memory cell transistors MT5a, MT5b, MT5c, MT5d, . . . , and MT5n include a plurality of floating gate electrodes FG5a, FG5b, FG5c, FG5d, . . . , and FG5n, respectively. A select gate transistor ST5b including a select gate electrode SG5b is serially connected to the memory cell transistor MT5n.

In the sixth column 101f, a select gate transistor ST6a including a select gate electrode SG6a is disposed. A plurality of memory cell transistors MT6a, MT6b, MT6c, MT6d, . . . , and MT6n are serially connected to the select gate transistor ST6a. The plurality of memory cell transistors MT6a, MT6b, MT6c, MT6d, . . . , and MT6n include a plurality of floating gate electrodes FG6a, FG6b, FG6c, FG6d, . . . , and FG6n, respectively. A select gate transistor ST6b including a select gate electrode SG6b is serially connected to the memory cell transistor MT6n.

In the seventh column 101g, a select gate transistor ST7a including a select gate electrode SG7a is disposed. A plurality of memory cell transistors MT7a, MT7b, MT7c, MT7d, . . . , and MT7n are serially connected to the select gate transistor ST7a. The plurality of memory cell transistors MT7a, MT7b, MT7c, MT7d, . . . , and MT7n include a plurality of floating gate electrodes FG7a, FG7b, FG7c, FG7d, . . . , and FG7n, respectively. A select gate transistor ST7b including a select gate electrode SG7b is serially connected to the memory cell transistor MT7n.

In the n-th column 101n, a select gate transistor STna including a select gate electrode SGna is disposed. A plurality of memory cell transistors MTna, MTnb, MTnc, MTnd, . . . , and MTnn are serially connected to the select gate transistor STna. The plurality of memory cell transistors MTna, MTnb, MTnc, MTnd, . . . , and MTnn include a plurality of floating gate electrodes FGna, FGnb, FGnc, FGnd, . . . , and FGnn, respectively. A select gate transistor STnb including a select gate electrode SGnb is serially connected to the memory cell transistor MTnn. Therefore, the semiconductor memory according to the embodiment includes the plurality of floating gate electrodes FG1a-FGnn that are arranged in a matrix.

A select gate line SSL is connected to the plurality of select gate transistors ST1a, ST2a, ST3a, ST4a, ST5a, ST6a, ST7a, , and Stna. A word line WL1 is connected to the plurality of memory cell transistors MT1a, MT2a, MT3a, MT4a, MT5a, MT6a, MT7a, . . . , and Mtna. A word line WL2 is connected to the plurality of memory cell transistors MT1b, MT2b, MT3b, MT4b, MT5b, MT6b, MT7b, . . . , and MTnb. A word line WL3 is connected to the plurality of memory cell transistors MT1c, MT2c, MT3c, MT4c, MT5c, MT6c, MT7c, . . . , and MTnc. A word line WL4 is connected to the plurality of memory cell transistors MT1d, MT2d, MT3d, MT4d, MT5d, MT6d, MT7d, . . . , and MTnd. A word line WLn is connected to the plurality of memory cell transistors MT1n, MT2n, MT3n, MT4n, MT5n, MT6n, MT7n, . . . , and MTnn. A select gate line GSL is connected to the plurality of select gate transistors ST1b, ST2b, ST3b, ST4b, ST5b, ST6b, ST7b, . . . , and STnb. Further, as shown in FIG. 1, a plurality of isolation insulators such as a plurality of shallow trench isolations STIs isolate the first column 101a, the second column 101b, the third column 101c, the fourth column 101d, the fifth column 101e, the sixth column 101f, the seventh column 101g, and the n-th column 101n in a column direction of the matrix. Here, the “column direction” is parallel to the length directions of the first to n-th columns 101a-101n.

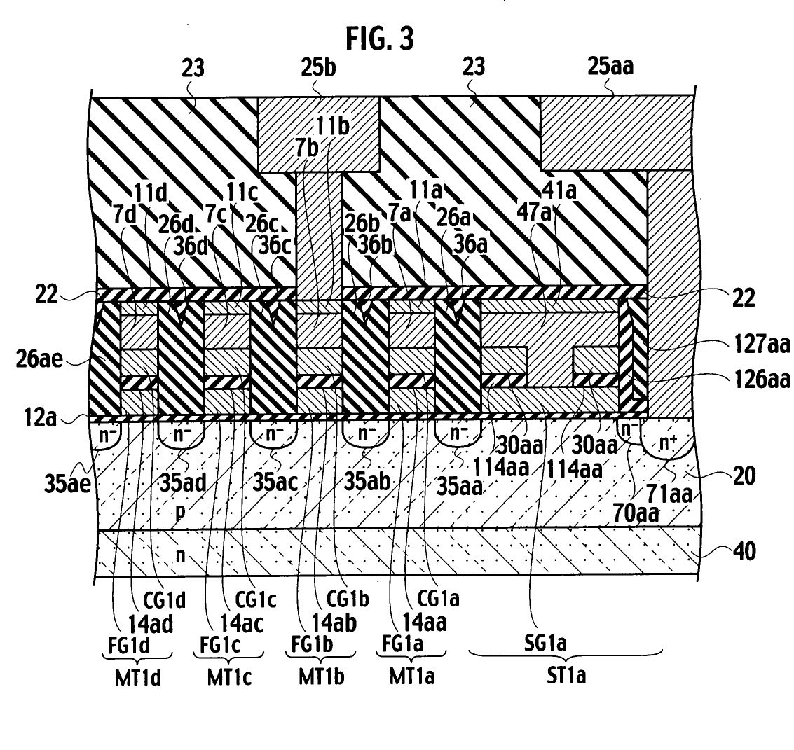

The sectional view of FIG. 3 taken on line III-III in FIG. 1 shows the select gate transistor ST1a. The select gate transistor ST1a is configured by an n-type semiconductor region 40, a p-type semiconductor region 20 disposed on the n-type semiconductor region 40, n⁻type diffusion regions 70aa, 35aa provided separately in the p-type semiconductor region 20 along a surface of the p-type semiconductor region 20, a tunnel insulating layer 12a disposed on the p-type semiconductor region 20, and the select gate electrode SG1a disposed on the tunnel insulating layer 12a. A select gate insulating layer 114aa is disposed on the select gate electrode SG1a. An upper electrode 30aa is disposed on the select gate insulating layer 114aa. A wiring portion 47a is disposed on the upper electrode 30aa. The wiring portion 47a penetrates the upper electrode 30aa and the select gate insulating layer 114aa and is electrically connected to the select gate electrode SG1a. A silicide layer 41a is disposed on the wiring portion 47a. The wiring portion 47a and the silicide layer 41a collectively implement the select gate line SSL shown in FIGS. 1 and 2.

With reference again to FIG. 3, the p-type semiconductor region 20, n⁻type diffusion regions 35aa, 35ab provided separately in the p-type semiconductor region 20 along the surface of the p-type semiconductor region 20, the tunnel insulating layer 12a disposed on the p-type semiconductor region 20, the floating gate electrode FG1a disposed on the tunnel insulating layer 12a, an inter-gate insulating layer 14aa disposed only on the floating gate electrode FG1a, and a control gate electrode CG1a disposed on the inter-gate insulating layer 14aa collectively implement the memory cell transistor MT1a. A wiring portion 7a is disposed on the control gate electrode CG1a and the wiring portion 7a is electrically connected to the control gate electrode CG1a in a row direction of the matrix. Here, the “row direction” is perpendicular to the column direction. A silicide layer 11a is disposed on the wiring portion 7a. The wiring portion 7a and the silicide layer 11a collectively implement the word line WL1 shown in FIGS. 1 and 2.

With reference again to FIG. 3, the p-type semiconductor region 20, n⁻type diffusion regions 35ab, 35ac provided separately in the p-type semiconductor region 20 along the surface of the p-type semiconductor region 20, the tunnel insulating layer 12a disposed on the p-type semiconductor region 20, the floating gate electrode FG1b disposed on the tunnel insulating layer 12a, an inter-gate insulating layer 14ab disposed only on the floating gate electrode FG1b, and a control gate electrode CG1b disposed on the inter-gate insulating layer 14ab collectively implement the memory cell transistor MT1b. A wiring portion 7b is disposed on the control gate electrode CG1b and the wiring portion 7b is electrically connected to the control gate electrode CG1b. A silicide layer 11b is disposed on the wiring portion 7b. The wiring portion 7b and the silicide layer 11b collectively implement the word line WL2 shown in FIGS. 1 and 2.

With reference again to FIG. 3, the p-type semiconductor region 20, n⁻type diffusion regions 35ac, 35ad provided separately in the p-type semiconductor region 20 along the surface of the p-type semiconductor region 20, the tunnel insulating layer 12a disposed on the p-type semiconductor region 20, the floating gate electrode FG1c disposed on the tunnel insulating layer 12a, an inter-gate insulating layer 14ac disposed only on the floating gate electrode FG1c, and a control gate electrode CG1c disposed on the inter-gate insulating layer 14ac collectively implement the memory cell transistor MT1c. A wiring portion 7c is disposed on the control gate electrode CG1c and the wiring portion 7c is electrically connected to the control gate electrode CG1c. A silicide layer 11c is disposed on the wiring portion 7c. The wiring portion 7c and the silicide layer 11c collectively implement the word line WL3 shown in FIGS. 1 and 2.

With reference again to FIG. 3, the p-type semiconductor region 20, n⁻type diffusion regions 35ad, 35ae provided separately in the p-type semiconductor region 20 along the surface of the p-type semiconductor region 20, the tunnel insulating layer 12a disposed on the p-type semiconductor region 20, the floating gate electrode FG1d disposed on the tunnel insulating layer 12a, an inter-gate insulating layer 14ad disposed only on the floating gate electrode FG1d, and a control gate electrode CG1d disposed on the inter-gate insulating layer 14ad collectively implement the memory cell transistor MT1d. A wiring portion 7d is disposed on the control gate electrode CG1d and the wiring portion 7d is electrically connected to the control gate electrode CG1d. A silicide layer 11d is disposed on the wiring portion 7d. The wiring portion 7d and the silicide layer 11d collectively implement the word line WL4 shown in FIGS. 1 and 2. A sidewall insulator 126aa is disposed laterally along a sidewall of the stacked select gate electrode SG1a, upper electrode 30aa, wiring portion 47a, and silicide layer 41a. The sidewall insulator 126aa is disposed on the opposite side of the memory cell transistor MT1a. Further, an insulator 127aa is disposed along the sidewall insulator 126aa.

A plurality of sidewall insulators 26a, 26b, 26c, and 26d are disposed on the tunnel insulating layer 12a. The sidewall insulator 26a isolates the select gate electrode SG1a and the floating gate electrode FG1a. Also, the sidewall insulator 26a isolates the stack of the upper electrode 30aa, the wiring portion 47a and the silicide layer 41a and the stack of the control gate electrode CG1a, the wiring portion 7a, and the silicide layer 11a. The sidewall insulator 26b isolates the floating gate electrode FG1a and the floating gate electrode FG1b. Also, the sidewall insulator 26b isolates the stack of the control gate electrode CG1a, the wiring portion 7a, and the silicide layer 11a and the stack of the control gate electrode CG1b, the wiring portion 7b, and the silicide layer 11b. The sidewall insulator 26c isolates the floating gate electrode FG1b and the floating gate electrode FG1c. Also, the sidewall insulator 26b isolates the stack of the control gate electrode CG1b, the wiring portion 7b, and the silicide layer 11b and the stack of the control gate electrode CG1c, the wiring portion 7c, and the silicide layer 11c. The sidewall insulator 26d isolates the floating gate electrode FG1c and the floating gate electrode FG1d. Also, the sidewall insulator 26d isolates the stack of the control gate electrode CG1c, the wiring portion 7c, and the silicide layer 11c and the stack of the control gate electrode CG1d, the wiring portion 7d, and the silicide layer 11d. Further, a sidewall insulator 26ae is disposed laterally along a sidewall of the stacked floating gate electrode FG1d, control gate electrode CG1d, wiring portion 7d, and silicide layer 11d. The sidewall insulator 26ae is disposed on the opposite side of the memory cell transistor MT1c.

An n⁺ semiconductor region 71aa is provided in the p-type semiconductor region 20 along the n diffusion region 70aa. A plurality of insulators 36aa, 36ab, 36ac, 36ad fill up a plurality of depressions in the sidewall insulators 26a, 26b, 26c, and 26d, respectively. A contiguous barrier insulator 22 is disposed on the plurality of silicide layers 41a, 11a, 11b, 11c, and 11d. Further, an interlevel insulator 23 is disposed on the barrier insulator 22. A contact stud 25b penetrates the barrier insulator 22 and the interlevel insulator 23. The contact stud 25b is electrically connected to the silicide layer 11b. A contact stud 25aa is disposed on the n⁺ semiconductor region 71aa. The contact stud 25aa is electrically connected to the n⁺ semiconductor region 71aa. The contact stud 25aa penetrates the insulator 127aa, the barrier insulator 22, and the interlevel insulator 23.

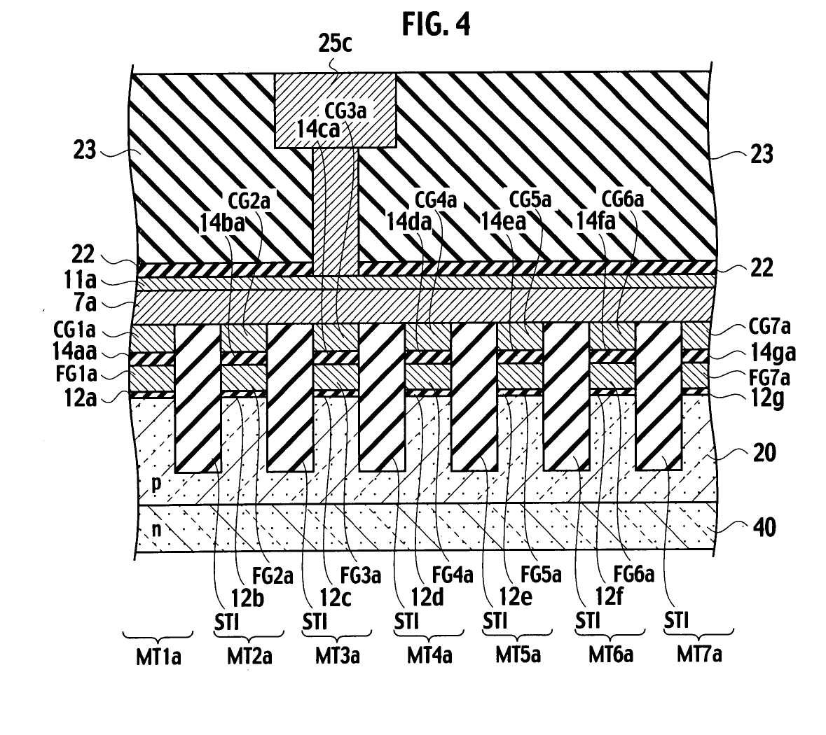

With reference to the sectional view of FIG. 4 taken on line IV-IV in FIG. 1, the tunnel insulating layer 12a and a plurality of tunnel insulating layers 12b, 12c, 12d, 12e, 12f, and 12g are disposed on the surface of the p-type semiconductor region 20. The plurality of parallel tunnel insulating layers 12a, 12b, 12c, 12d, 12e, 12f, and 12g extend in the column direction. The isolated floating gate electrode FG1a of the memory cell transistor MT1a is disposed on the tunnel insulating layer 12a. The inter-gate insulating layer 14aa is disposed only on the floating gate electrode FG1a. The control gate electrode CG1a is disposed on the inter-gate insulating layer 14aa. The isolated floating gate electrode FG2a of the memory cell transistor MT2a is disposed on the tunnel insulating layer 12b. The inter-gate insulating layer 14ba is disposed only on the floating gate electrode FG2a. The control gate electrode CG2a is disposed on the inter-gate insulating layer 14ba. The isolation insulator STI extends between arrangements of the control gate electrodes CG1a and CG2a along the column direction of the matrix to penetrate into the interior of the p-type semiconductor region 20. Therefore, the isolation insulator STI isolates the control gate electrode CG1a and the control gate electrode CG2a from each other in the column direction. And, the isolation insulator STI isolates the inter-gate insulating layer 14aa and the inter-gate insulating layer 14ba from each other in the column direction. Also, the isolation insulator STI isolates the floating gate electrode FG1a and the floating gate electrode FG2a from each other in the column direction. Further, the isolation insulator STI isolates the tunnel insulating layer 12a and the tunnel insulating layer 12b from each other in the column direction.

The isolated floating gate electrode FG3a of the memory cell transistor MT3a is disposed on the tunnel insulating layer 12c. The inter-gate insulating layer 14ca is disposed only on the floating gate electrode FG3a. The control gate electrode CG3a is disposed on the inter-gate insulating layer 14ca. The isolation insulator STI extends between arrangements of the control gate electrodes CG2a and CG3a along the column direction to penetrate into the interior of the p-type semiconductor region 20. Therefore, the isolation insulator STI isolates the control gate electrode CG2a and the control gate electrode CG3a from each other in the column direction. And, the isolation insulator STI isolates the inter-gate insulating layer 14ba and the inter-gate insulating layer 14ca from each other in the column direction. Also, the isolation insulator STI isolates the floating gate electrode FG2a and the floating gate electrode FG3a from each other in the column direction. Further, the isolation insulator STI isolates the tunnel insulating layer 12b and the tunnel insulating layer 12c from each other in the column direction.

The isolated floating gate electrode FG4a of the memory cell transistor MT4a is disposed on the tunnel insulating layer 12d. The inter-gate insulating layer 14da is disposed only on the floating gate electrode FG4a. The control gate electrode CG4a is disposed on the inter-gate insulating layer 14da. The isolation insulator STI extends between the control gate electrodes CG3a and CG4a along the column direction to penetrate into the interior of the p-type semiconductor region 20. Therefore, the isolation insulator STI isolates the control gate electrode CG3a and the control gate electrode CG4a from each other in the column direction. And, the isolation insulator STI isolates the inter-gate insulating layer 14ca and the inter-gate insulating layer 14da from each other in the column direction. Also, the isolation insulator STI isolates the floating gate electrode FG3a and the floating gate electrode FG4a from each other in the column direction. Further, the isolation insulator STI isolates the tunnel insulating layer 12c and the tunnel insulating layer 12d from each other in the column direction.

The isolated floating gate electrode FG5a of the memory cell transistor MT5a is disposed on the tunnel insulating layer 12e. The inter-gate insulating layer 14ea is disposed only on the floating gate electrode FG5a. The control gate electrode CG5a is disposed on the inter-gate insulating layer 14ea. The isolation insulator STI extends between the control gate electrodes CG4a and CG5a along the column direction to penetrate into the interior of the p-type semiconductor region 20. Therefore, the isolation insulator STI isolates the control gate electrode CG4a and the control gate electrode CG5a from each other in the column direction. And, the isolation insulator STI isolates the inter-gate insulating layer 14da and the inter-gate insulating layer 14ea from each other in the column direction. Also, the isolation insulator STI isolates the floating gate electrode FG4a and the floating gate electrode FG5a from each other in the column direction. Further, the isolation insulator STI isolates the tunnel insulating layer 12d and the tunnel insulating layer 12e from each other in the column direction.

The isolated floating gate electrode FG6a of the memory cell transistor MT6a is disposed on the tunnel insulating layer 12f. The inter-gate insulating layer 14fa is disposed only on the floating gate electrode FG6a. The control gate electrode CG6a is disposed on the inter-gate insulating layer 14fa. The isolation insulator STI extends between the control gate electrodes CG5a and CG6a along the column direction to penetrate into the interior of the p-type semiconductor region 20. Therefore, the isolation insulator STI isolates the control gate electrode CG5a and the control gate electrode CG6a from each other in the column direction. And, the isolation insulator STI isolates the inter-gate insulating layer 14ea and the inter-gate insulating layer 14fa from each other in the column direction. Also, the isolation insulator STI isolates the floating gate electrode FG5a and the floating gate electrode FG6a from each other in the column direction. Further, the isolation insulator STI isolates the tunnel insulating layer 12e and the tunnel insulating layer 12f from each other in the column direction.

The isolated floating gate electrode FG7a of the memory cell transistor MT7a is disposed on the tunnel insulating layer 12g. The inter-gate insulating layer 14ga is disposed only on the floating gate electrode FG7a. The control gate electrode CG7a is disposed on the inter-gate insulating layer 14ga. The isolation insulator STI extends between the control gate electrodes CG6a and CG7a along the column direction to penetrate into the interior of the p-type semiconductor region 20. Therefore, the isolation insulator STI isolates the control gate electrode CG6a and the control gate electrode CG7a from each other in the column direction. And, the isolation insulator STI isolates the inter-gate insulating layer 14fa and the inter-gate insulating layer 14ga from each other in the column direction. Also, the isolation insulator STI isolates the floating gate electrode FG6a and the floating gate electrode FG7a from each other in the column direction. Further, the isolation insulator STI isolates the tunnel insulating layer 12f and the tunnel insulating layer 12g from each other in the column direction.

The contiguous wiring portion 7a is disposed on the plurality of control gate electrodes CG1a, CG2a, CG3a, CG4a, CG5a, CG6a, and CG7a arranged along the row direction. The wiring portion 7a runs along the row direction and share the plurality of control gate electrodes CG1a, CG2a, CG3a, CG4a, CG5a, CG6a, and CG7a. The wiring portion 7a electrically couples the plurality of control gate electrodes CG1a, CG2a, CG3a, CG4a, CG5a, CG6a, and CG7a. The silicide layer 11a is disposed on the wiring portion 7a. The wiring portion 7a and the silicide layer 11a collectively implement the word line WL1 shown in FIGS. 1 and 2. In FIG. 4, the barrier insulator 22 is disposed on the silicide layer 11a. The interlevel insulator 23 is disposed on the barrier insulator 22. A contact stud 25c penetrates the barrier insulator 22 and the interlevel insulator 23. The contact stud 25c is electrically connected to the silicide layer 11a.

In the semiconductor memory shown in FIGS. 1, 3, and 4, it is possible to use polycrystal silicon (Si) or the like as the material for the plurality of floating gate electrodes FG1a-FGnn, the plurality of select gate electrodes SG1a- SGnb, the plurality of control gate electrodes CG1a-CG7a, the upper electrode 30aa, and the plurality of wiring portions 7a-7d, and 47a, respectively. Alternatively, titanium silicide (TiSi₂), cobalt silicide (COSi₂), and nickel silicide (NiSi₂) can be used as the materials of the plurality of control gate electrodes CG1a-CG7a. As the materials for the silicide layers 11a-11d, 41a, respectively, it is possible to use the suicides of a refractory metal such as TiSi₂, COSi₂, NiSi₂, platinum silicide (PtSi), molybdenum silicide (MOSi₂), and erbium silicide (ErSi₂), or the like. As the materials used respectively for the plurality of tunnel insulating layers 12a-12g, the plurality of inter-gate insulating layers 14aa-14ga, the select gate insulating layer 114aa, the plurality of isolation insulators STIs, the plurality of sidewall insulators 26a- 26e, 62a, and 126aa-126ga, the insulators 36aa-36ad, and 127aa, the barrier insulator 22, and the interlevel insulator 23, it is possible to use silicon dioxide (SiO₂), silicon nitride (Si₃N₄), hafnium oxide (HfO₂), tantalum pentoxide (Ta₂O₅), titanium oxide (TiO₂), alumina (Al₂O₃), zirconium oxide (ZrO₂), oxide-nitride-oxide (ONO), phosphorsilicate glass (PSG), borophosphosilicate glass (BPSG), silicon oxy nitride (SiON), barium titanate (BaTiO₃) fluorine-doped silicon oxide (SiOₓF_{y}), and organic polymer such as polyimide, for example. As the materials used respectively for the plurality of contact studs 25aa, 25b, and 25c, it is possible to use electric conductor such as aluminium (Al) and copper (Cu), for example.

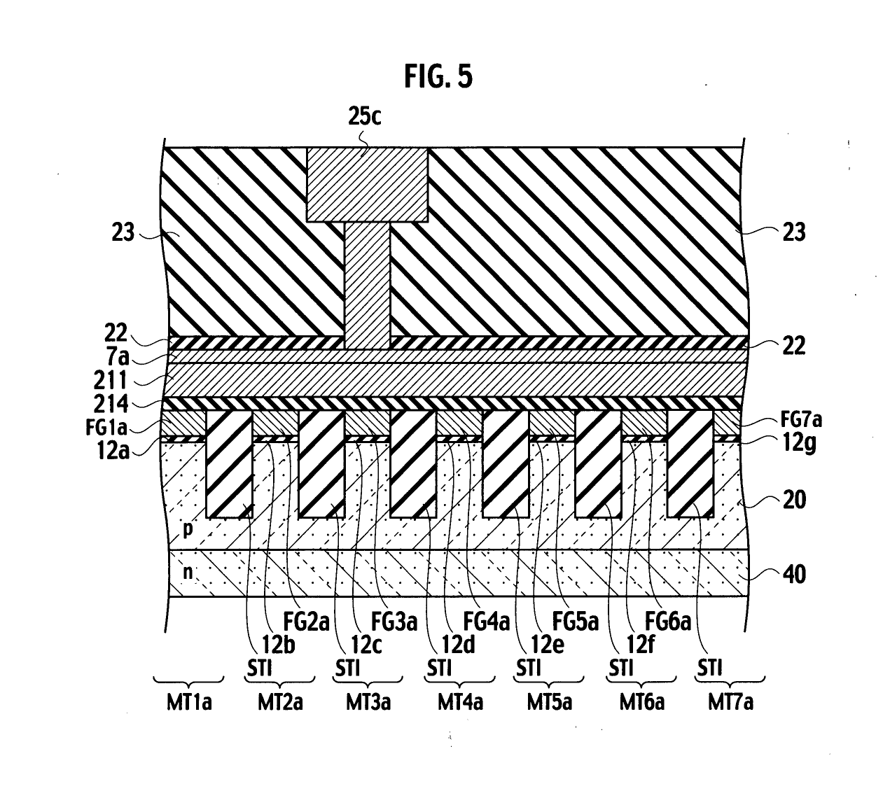

As described above, in the semiconductor memory shown in FIGS. 1 to 4, the plurality of isolation insulators STIs isolate the plurality of inter-gate insulating layers 14aa-14ga disposed only on the plurality of floating gate electrodes FG1a-FGnn, respectively. On the contrary, with reference to FIG. 5, a semiconductor memory according to a comparative example includes a common inter-gate insulating layer 214. The common inter-gate insulating layer 214 is disposed on the plurality of floating gate electrode FG1a-FG7n. Therefore, the contiguous common inter-gate insulating layer 214 is connected to all of the plurality of floating gate electrode FG1a-FG7n. A control gate electrode wiring 211 is disposed on the common inter-gate insulating layer 214. For a nonvolatile semiconductor memory, it is necessary to electrically isolate the plurality of floating gate electrodes FG1a-FG7n among the adjacent memory cell transistors in order to retain a plurality of charges for a long time. However, if the charge trap level is located in the common inter-gate insulating layer 214, the plurality of charges move among the plurality of floating gate electrodes FG1a-FG7n through the common inter-gate insulating layer 214. Consequently, the data retention reliability of the memory cell transistor according to the comparative example may fail. However, in the semiconductor memory shown in FIG. 4, the plurality of isolation insulators STIs isolate the plurality of inter-gate insulating layers 14aa-14ga from each other. Each of the isolation insulators STIs has a volume larger than each of the plurality of inter-gate insulating layers 14aa-14ga. Therefore, the plurality of isolation insulators STIs prevent the plurality of charges from moving among the plurality of floating gate electrodes FG1a-FG7n through the plurality of inter-gate insulating layers 14aa-14ga. As a result, the semiconductor memory according to the embodiment makes it possible to provide improved data retention reliability.

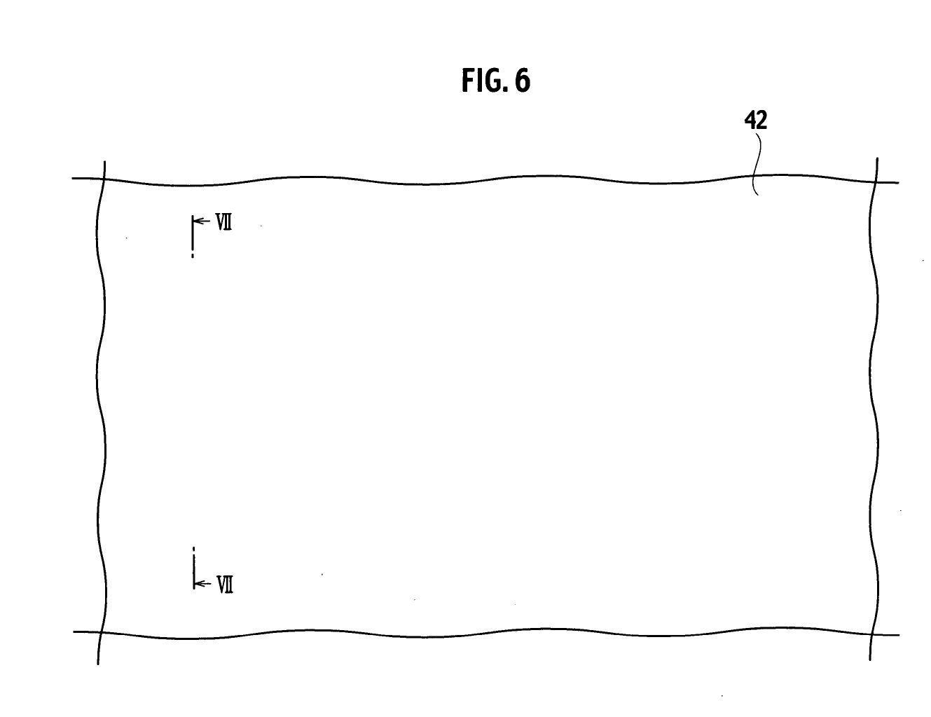

With reference next to FIGS. 6 to 40, a method for manufacturing the semiconductor memory according to the embodiment is described.

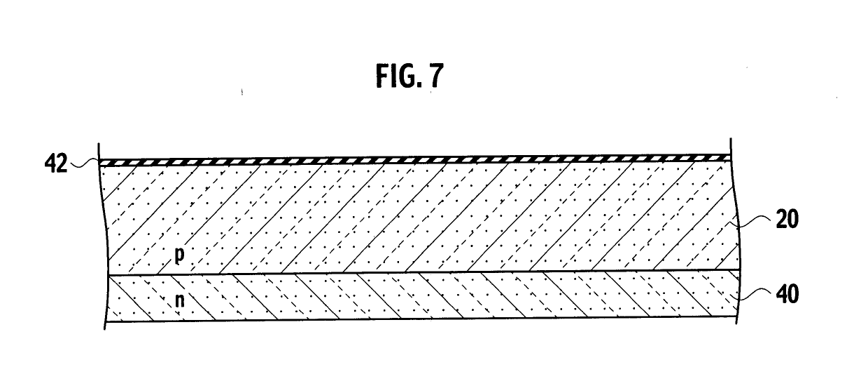

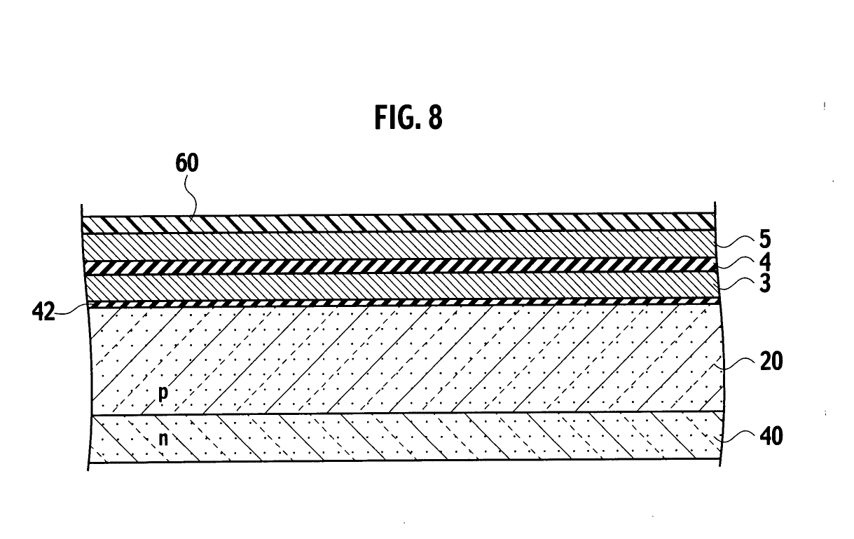

As shown in FIG. 6 and the sectional view of FIG. 7 taken on line VII-VII in FIG. 6, a tunnel insulating layer 42 is formed on the p-type semiconductor region 20 disposed on the n-type semiconductor region 40. The tunnel insulating layer 42 is formed by thermal oxidization or furnace processing. The tunnel insulating layer 42 is composed of SiO₂, for example. In FIG. 8, a polycrystalline silicon layer is deposited on the tunnel insulating layer 42 by a Chemical Vapor Deposition (CVD) process to form a first conducting layer 3 on the tunnel insulating layer 42. Further, an interlayer insulator 4 composed of SiO₂ is deposited on the first conducting layer 3 by the CVD process. Then, a second conducting layer 5 composed of the polycrystalline silicon is deposited on the interlayer insulator 4 by the CVD process.

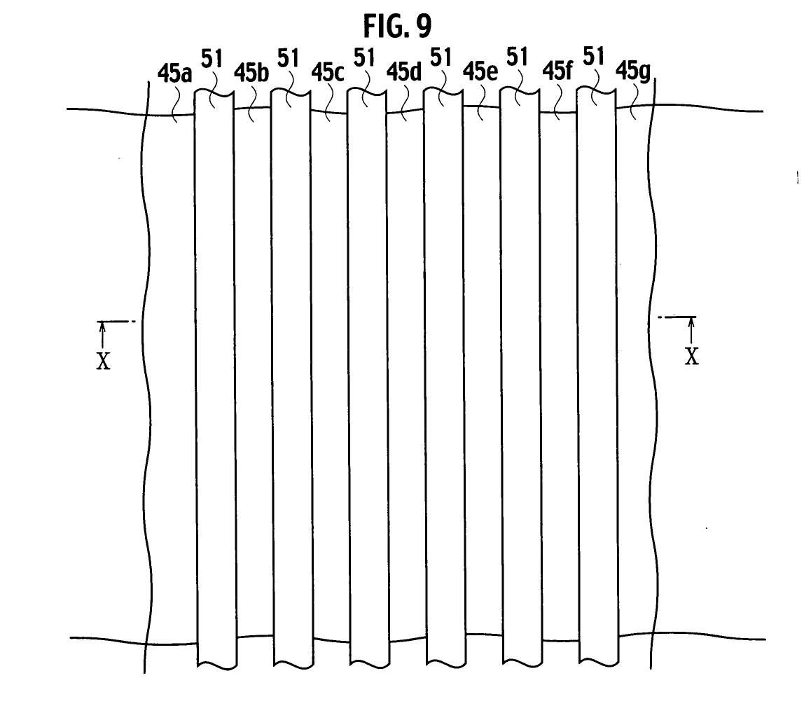

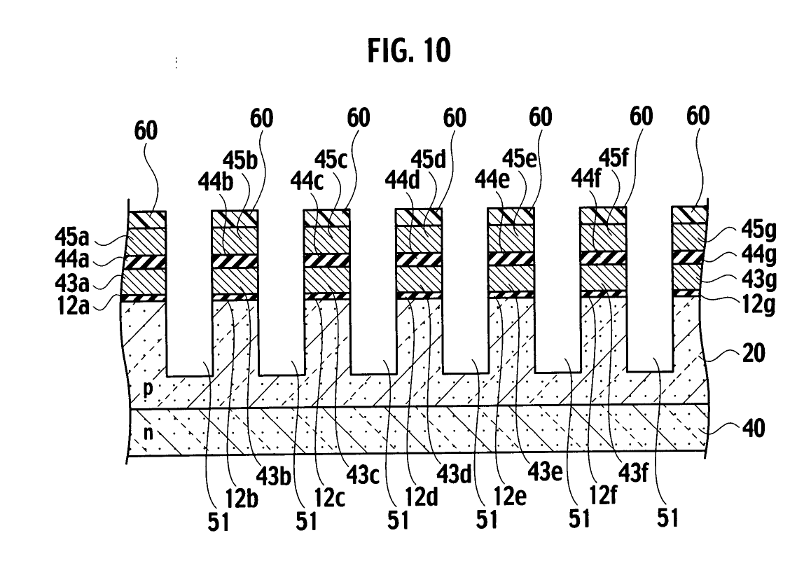

A photoresist is applied to the surface of the second conducting layer 5 to form an etch mask 60. Through use of optical lithography and an etch process, a plurality of openings are formed in the etch mask 60. Thereafter, the etch process is employed to divide the second conducting layer 5, and the interlayer insulator 4, the first conducting layer 3, and the tunnel insulating layer 42 into a plurality of strips of the second conducting layers 45a, 45b, 45c, 45d, 45e, 45f, and 45g, the interlayer insulators 44a, 44b, 44c, 44d, 44e, 44f, and 44g, the first conducting layers 43a, 43b, 43c, 43d, 43e, 43f, and 43g, and the tunnel insulating layers 12a, 12b, 12c, 12d, 12e, 12f, and 12g by using the etch mask 60. Consequently, as shown in FIG. 9 and the sectional view of FIG. 10 taken on line X-X in FIG. 9, a plurality of column isolation trenches 51 runs between the plurality of strips of the second conducting layers 45a, 45b, 45c, 45d, 45e, 45f, and 45g, the interlayer insulators 44a, 44b, 44c, 44d, 44e, 44f, and 44g, the first conducting layers 43a, 43b, 43c, 43d, 43e, 43f, and 43g, the tunnel insulating layer 12a, 12b, 12c, 12d, 12e, 12f, and 12g. Each of the column isolation trenches 51 penetrates to the interior of the p-type semiconductor region 20. The column isolation trenches 51 isolate the plurality of strips of the tunnel insulating layers 12a, 12b, 12c, 12d, 12e, 12f, and 12g formed on protruding portions of the p-type semiconductor region 20. And, each of the column isolation trenches 51 isolates the plurality of strips of the first conducting layers 43a, 43b, 43c, 43d, 43e, 43f, and 43g formed on the strips of tunnel insulating layers 12a, 12b, 12c, 12d, 12e, 12f, and 12g, respectively. Further, the column isolation trenches 51 isolate the strips of interlayer insulators 44a, 44b, 44c, 44d, 44e, 44f, and 44g formed on the strips of first conducting layers 43a, 43b, 43c, 43d, 43e, 43f, and 43g, respectively. Also, the column isolation trenches 51 isolate the strips of second conducting layers 45a, 45b, 45c, 45d, 45e, 45f, and 45g formed on the strips of interlayer insulators 44a, 44b, 44c, 44d, 44e, 44f, and 44g, respectively.

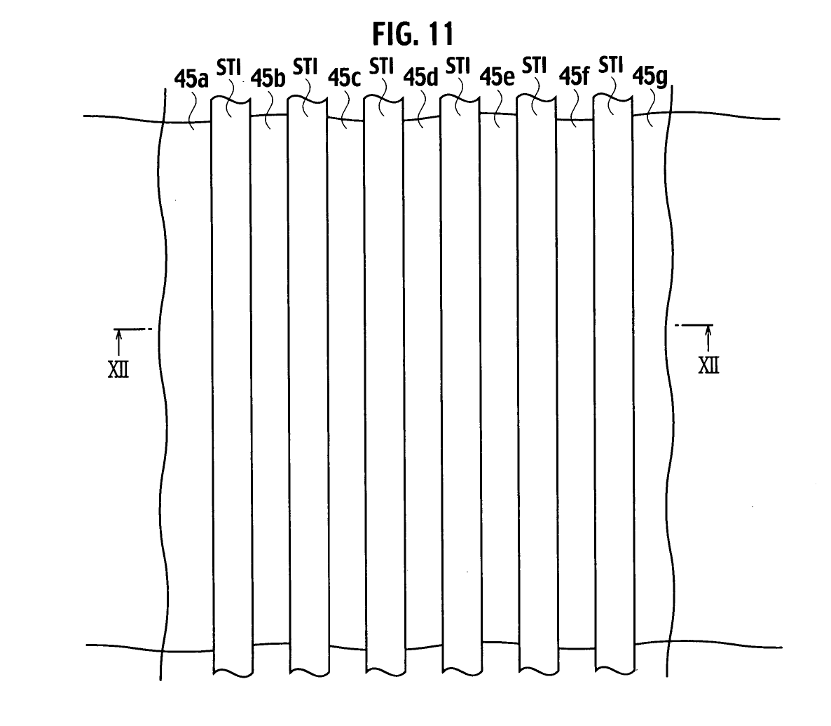

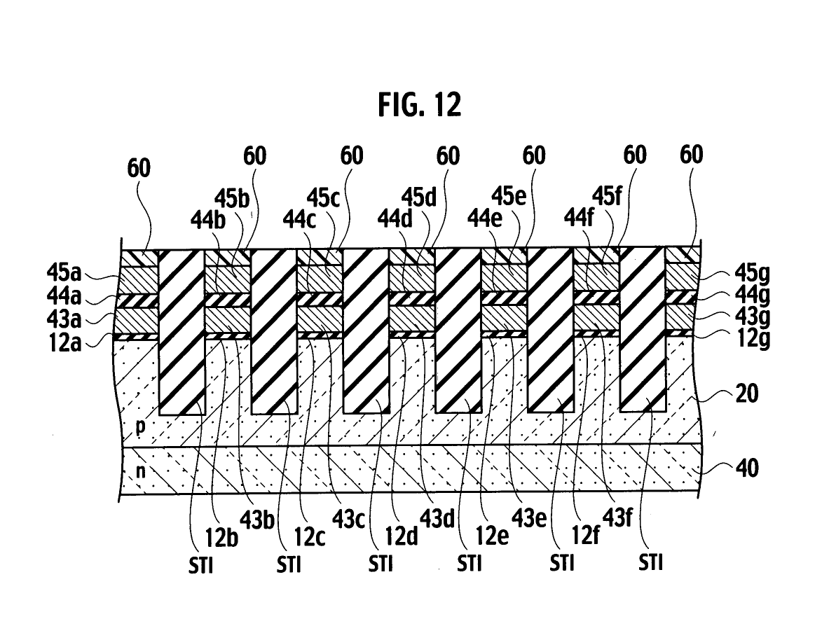

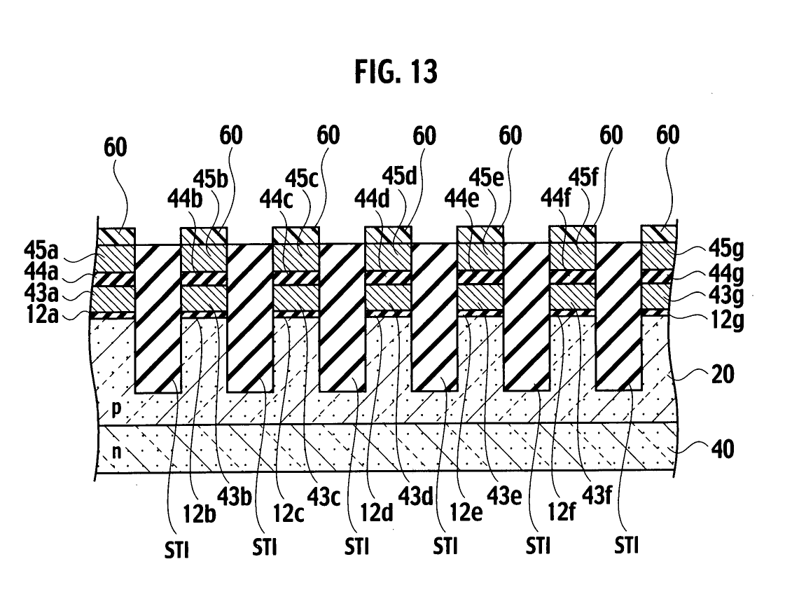

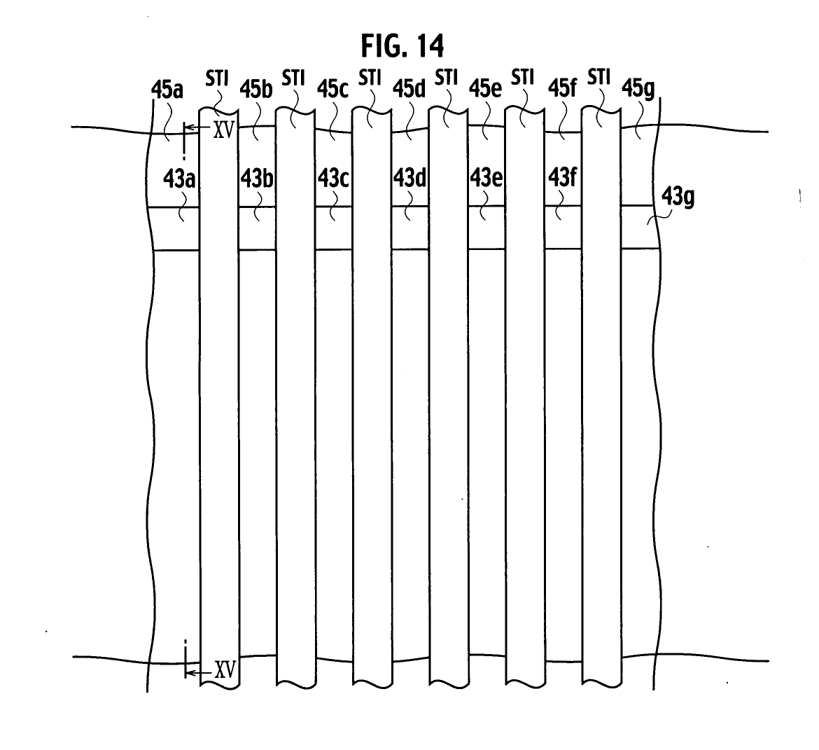

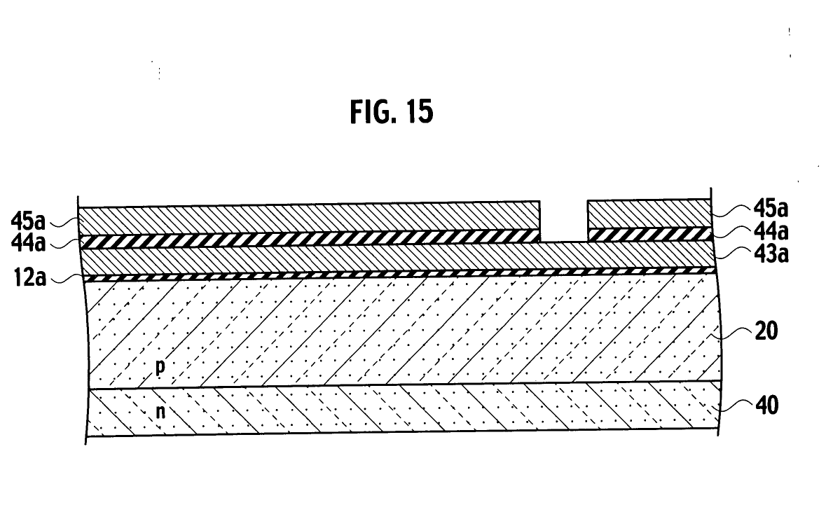

A polysilazane is coated on the strips of second conducting layers 45a, 45b, 45c, 45d, 45e, 45f, and 45g to fill the plurality of column isolation trenches 51 with the plurality of isolation insulators STIs composed of SiO₂. So, the plurality of strips of the interlayer insulators 44a, 44b, 44c, 44d, 44e, 44f, and 44g are isolated from each other in the column direction by the plurality of isolation insulators STIs. Then, a chemical mechanical planarization (CMP) process is employed to produce the planar surfaces of the isolation insulators STIs as shown in FIG. 11 and the sectional view of FIG. 12 taken on line XII-XII in FIG. 11. As shown in FIG. 13, the plurality of isolation insulators STIs may be etched back. Then, as shown in FIG. 14 and the sectional view of FIG. 15 taken on line XV-XV in FIG. 14, a plurality of portions in the strips of the second conducting layers 45a-45g and a plurality of portions in the strips of the interlayer insulators 44a-44g are selectively removed by optical lithography and the etch process until a plurality of portions in the strips of the first conducting layers 43a-43g are exposed.

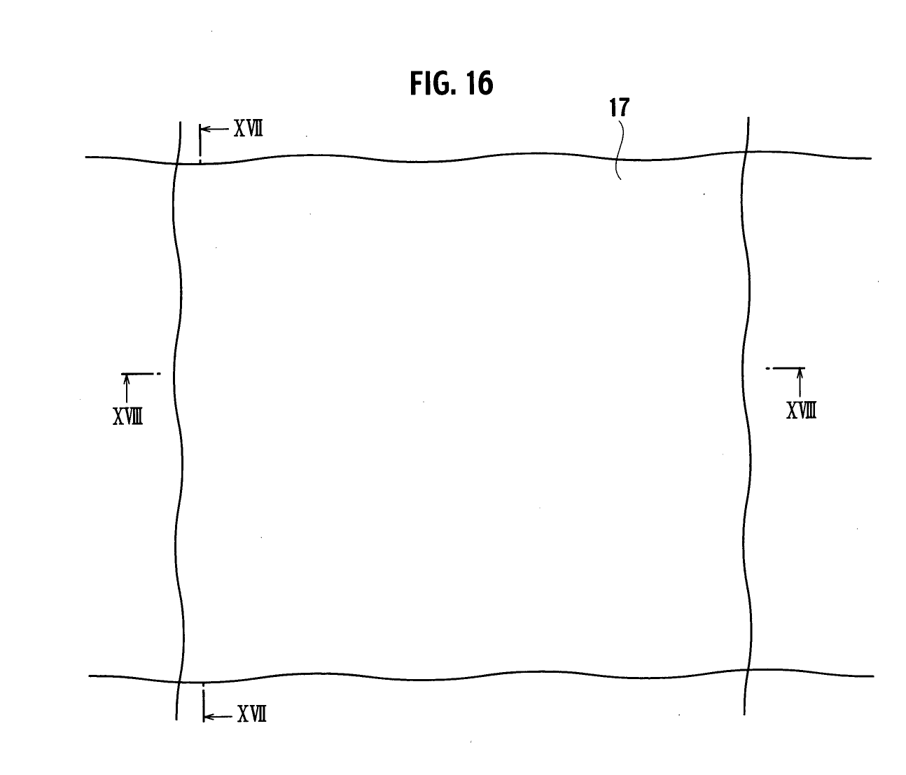

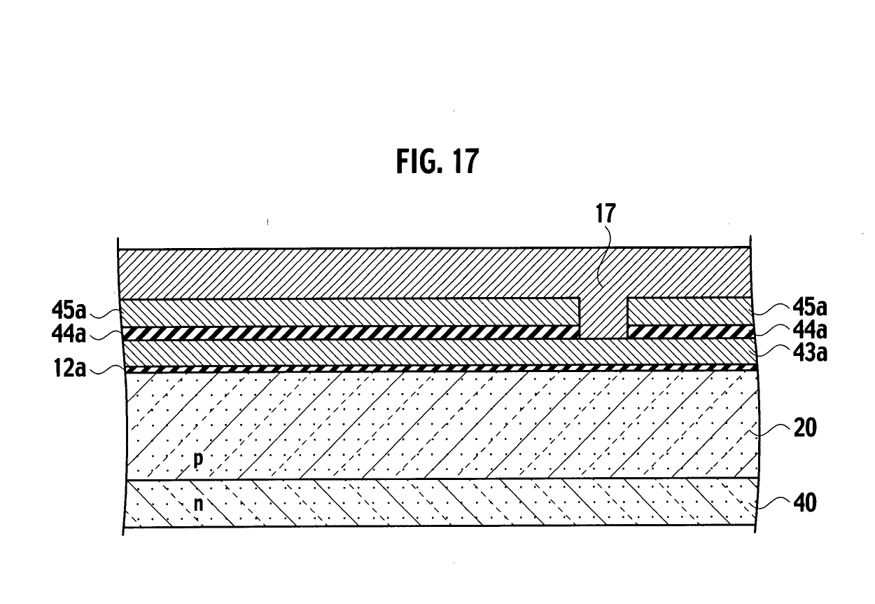

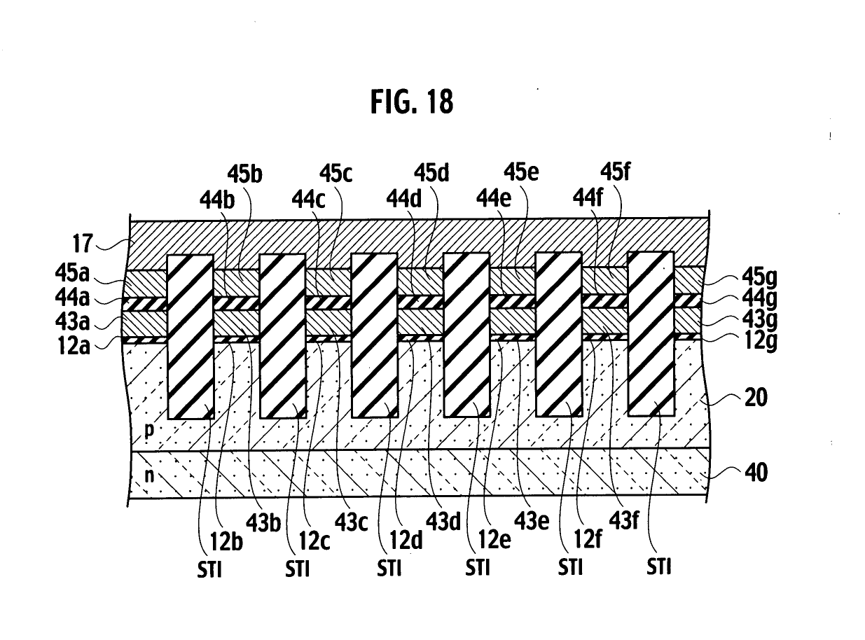

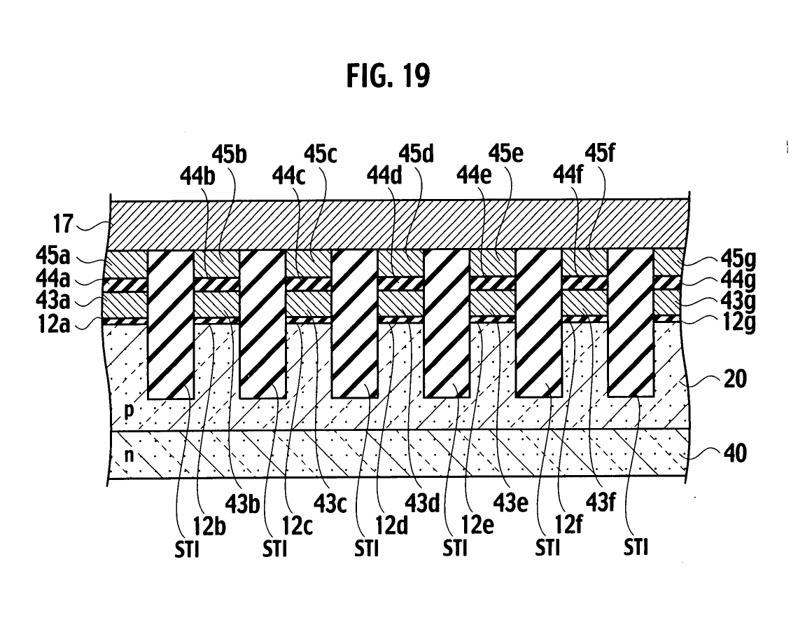

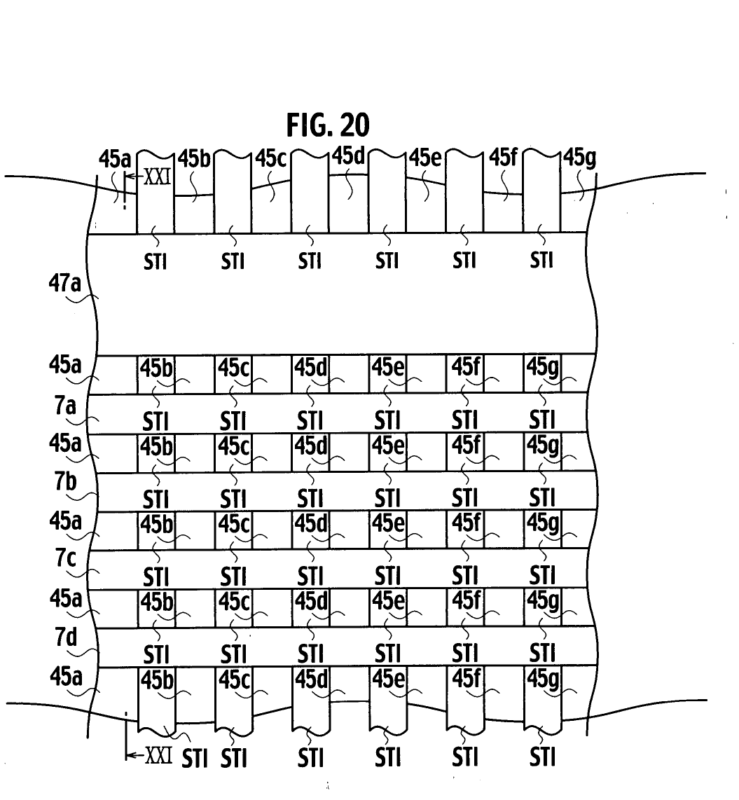

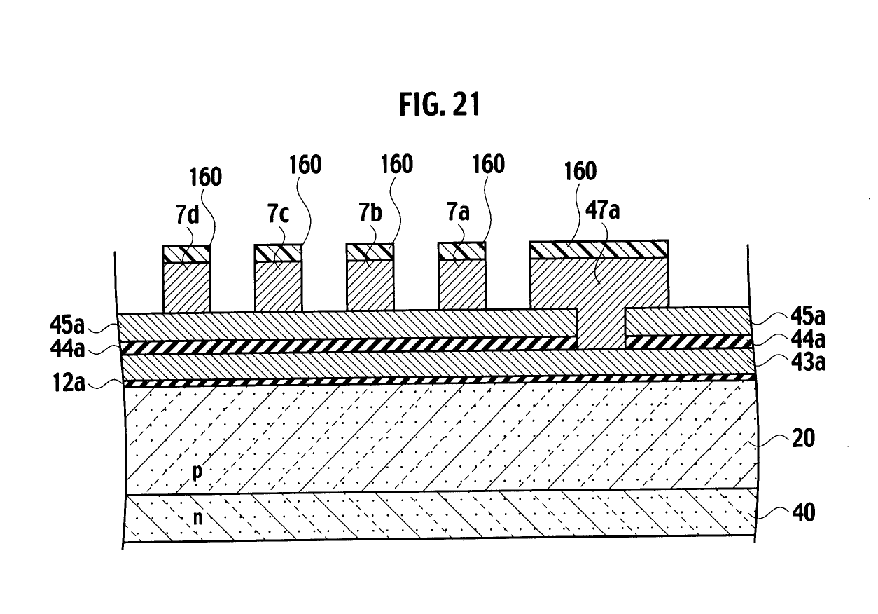

With reference to FIG. 16, the sectional view of FIG. 17 taken on line XVII-XVII in FIG. 16, and the sectional view of FIG. 18 taken on line XVIII-XVIII in FIG. 16, a third conducting layer 17 composed of the polycrystalline silicon is deposited by the CVD process on the plurality of second conducting layers 45a-45g. If the plurality of isolation insulators STIs are etched back as shown in FIG. 13, the sectional view taken on line XVIII-XVIII in FIG. 16 is FIG. 19. Next, an etch mask 160 composed of the photoresist is coated on the third conducting layer 17. Then, a plurality of openings are formed in the etch mask 160 by optical lithography and the etch process. Thereafter, the third conducting layer 17 is selectively removed by using the etch mask 160. Consequently, as shown in FIG. 20 and the sectional view of FIG. 21 taken on line XXI-XXI in FIG. 20, the plurality of wiring portions 7a, 7b, 7c, 7d, and 47a extending perpendicular to the length directions of the isolation insulators STIs are formed on the second conducting layers 45a-45g.

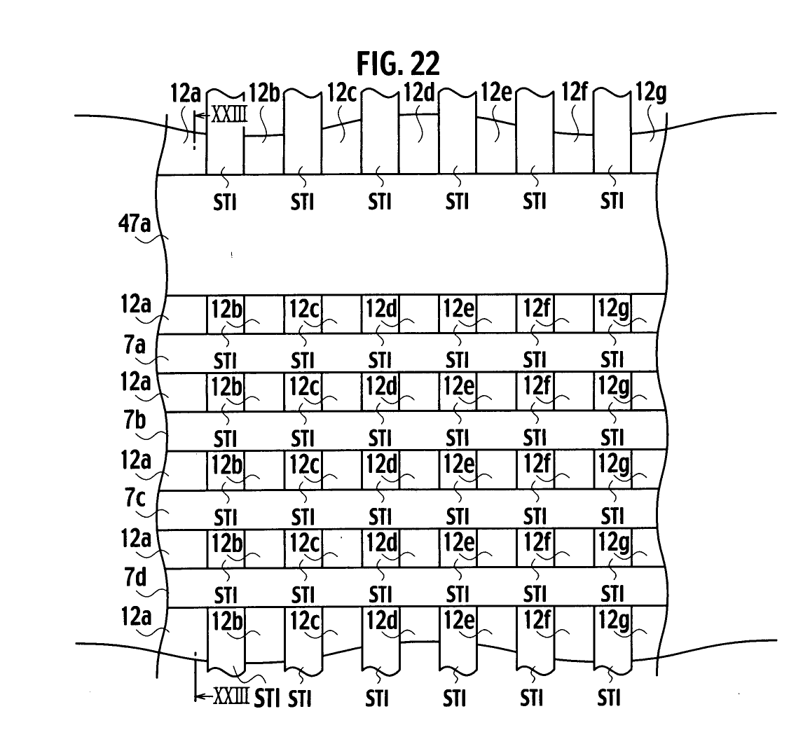

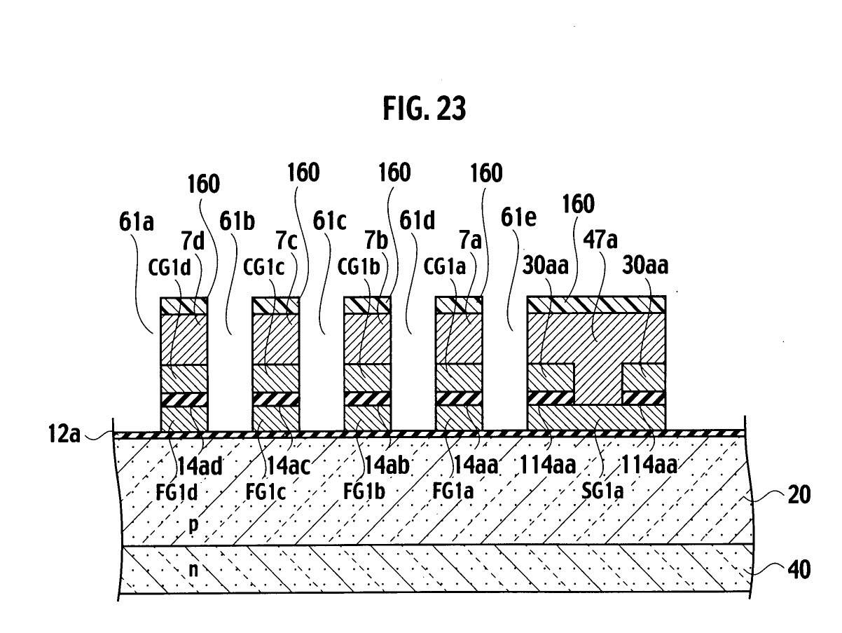

A plurality of portions of the second conducting layers 45a-45g, a plurality of portions of the inter layer insulators 44a-44g, and a plurality of portions of the first conducting layers 43a-43g are selectively removed until the plurality of tunnel insulating layers 12a-12g are exposed. Consequently, as shown in FIG. 22 and the sectional view of FIG. 23 taken on line XXIII-XXIII in FIG. 22, a plurality of row isolation trenches 61a, 61b, 61c, 61d, and 61e are delineated in the row direction. The plurality of row isolation trenches 61a, 61b, 61c, 61d, and 61e run along the row direction. Also, the upper electrode 30aa, the select gate insulating layer 114aa, the select gate electrode SG1a, the plurality of isolated control gate electrodes CG1a, CG1b, CG1c, and CG1d, the plurality of isolated inter-gate insulating layers 14aa, 14ab, 14ac, and 14ad, and the plurality of isolated floating gate electrodes FG1a, FG1b, FG1c, and FG1d are formed, respectively. As shown in FIGS. 18 and 19, each of the isolation insulators STIs is already filled in the column direction. Therefore, the plurality of inter-gate insulating layers 14aa-14ad shown in FIG. 23 are isolated from adjacent inter-gate insulating layers in the column direction by the isolation insulators STIs, respectively.

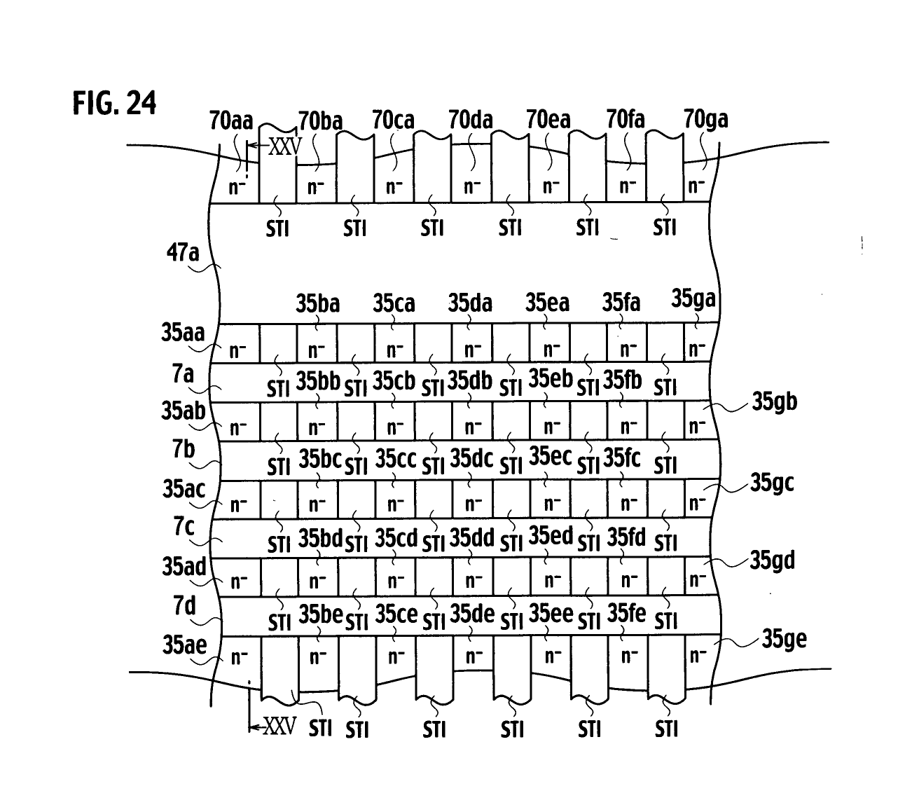

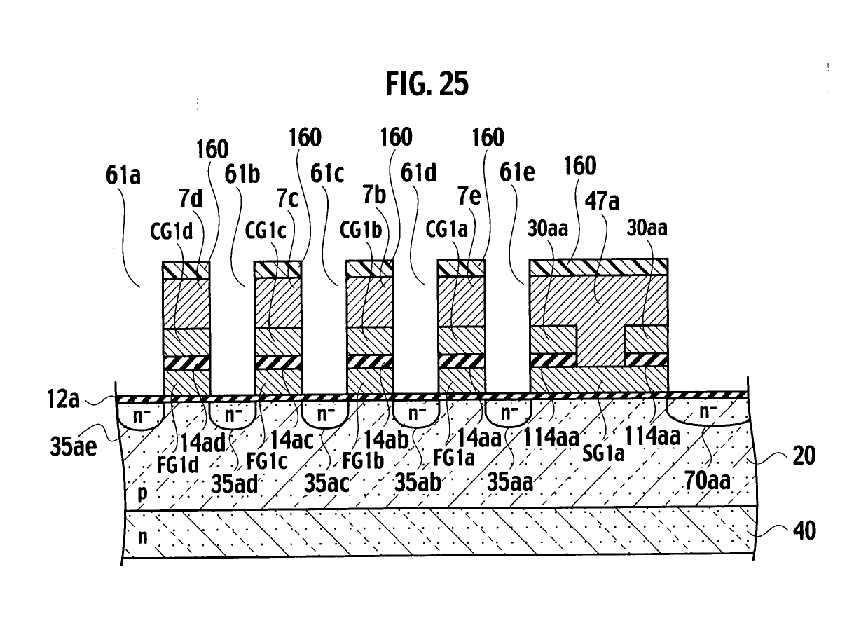

A plurality of portions of the p-type semiconductor region 20 shown in FIG. 23 are doped with N-type dopants such as phosphorus ions (P⁺) through the plurality of exposed tunnel insulating layers 12a, 12b, 12c, 12d, 12e, 12f, and 12g shown in FIG. 22. Thereafter, the plurality of n⁻type diffusion regions 70aa, 35aa, 35ab, 35ac, 35ad, and 35ae are formed in the p-type semiconductor region 20 as shown in FIG. 24 and the sectional view of FIG. 25 taken on line XXV-XXV in FIG. 24. Also, the plurality of n⁻type diffusion regions 70ba, 70ca, 70da, 70ea, 70fa, 70ga, 35ba, 35bb, 35bc, 35bd, 35be, 35ca, 35cb, 35cc, 35cd, 35ce, 35da, 35db, 35dc, 35dd, 35de, 35ea, 35eb, 35ec, 35ed, 35ee, 35fa, 35fb, 35fc, 35fd, 35fe, 35ga, 35gb, 35gc, 35gd, and 35ge are formed. It should be noted that the plurality of tunnel insulating layers 12a, 12b, 12c, 12d, 12e, 12f, and 12g are not shown in FIG. 24 in order to provide clarity.

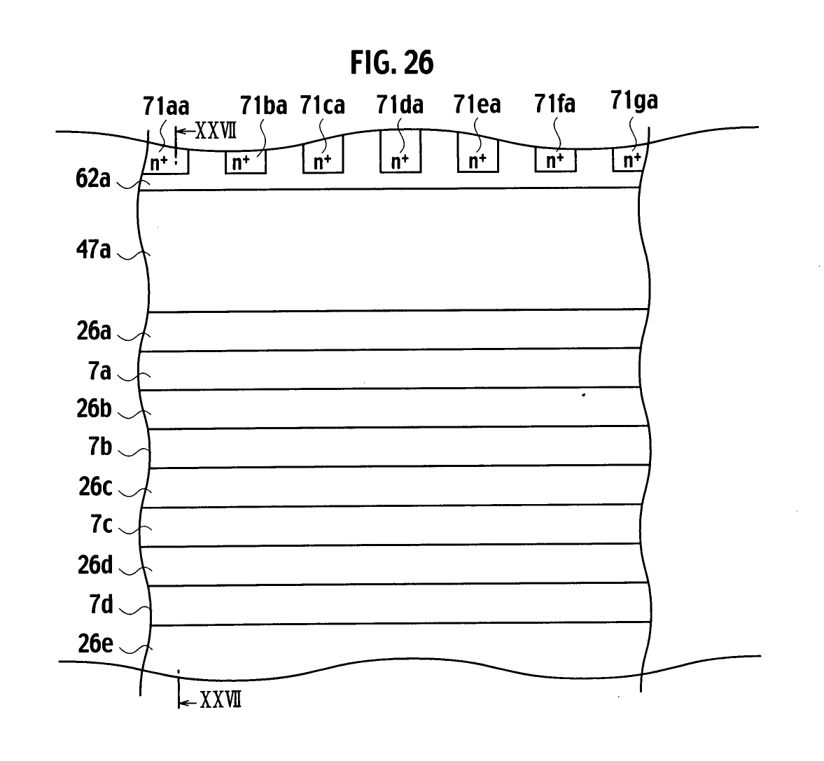

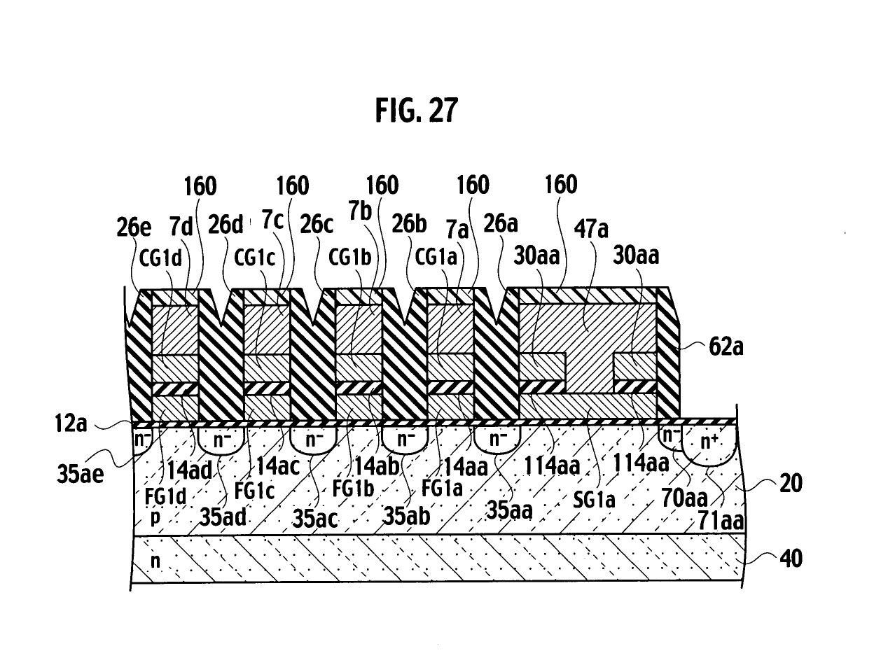

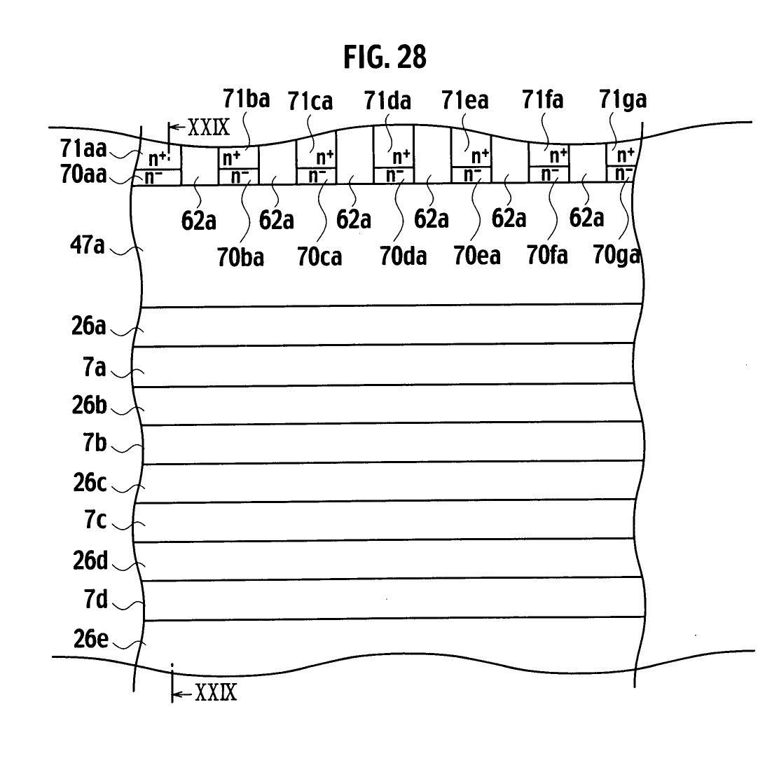

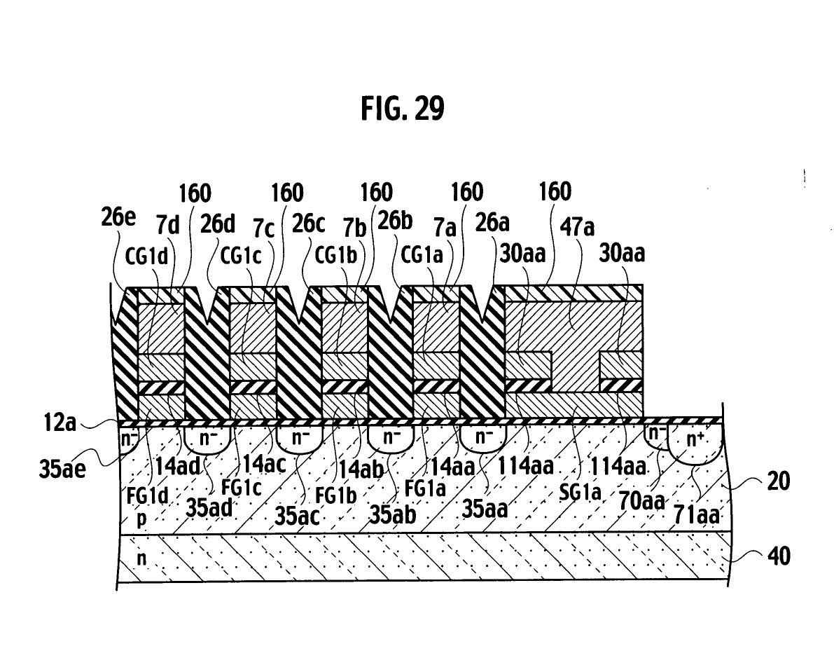

A SiO₂ insulator is deposited on the p-type semiconductor region 20 by using the CVD of tetraethylorthosilicate (TEOS) to fill the plurality of row isolation trenches 61a-61e. After the excess insulator is removed, as shown in FIG. 26 and the sectional view of FIG. 27 taken on line XXVII-XXVII in FIG. 26, the plurality of sidewall insulators 26a, 26b, 26c, 26d, 26e, and 62a are formed on the plurality of n-type diffusion regions 35aa, 35ab, 35ac, 35ad, 35ae, and 70aa, respectively. Here, each material for the plurality of sidewall insulators 26a-26e, and 62a has a larger etching selectivity ratio than each material for the plurality of floating gate electrodes FG1a-FG1d, the plurality of control gate electrodes CG1a-CG1d, and the plurality of wiring portions 7a-7d, and 47a. Then, the p-type semiconductor region 20 is selectively doped with the N-type dopants such as Arsenic ions (As⁺) to form the n⁺ semiconductor region 71aa adjacent to the n⁻ diffusion region 70aa. Further, as shown in FIG. 28 and the sectional view of FIG. 29 taken on line XXIX-XXIX in FIG. 28, a portion of the sidewall insulator 62a is selectively removed by the selective etching process.

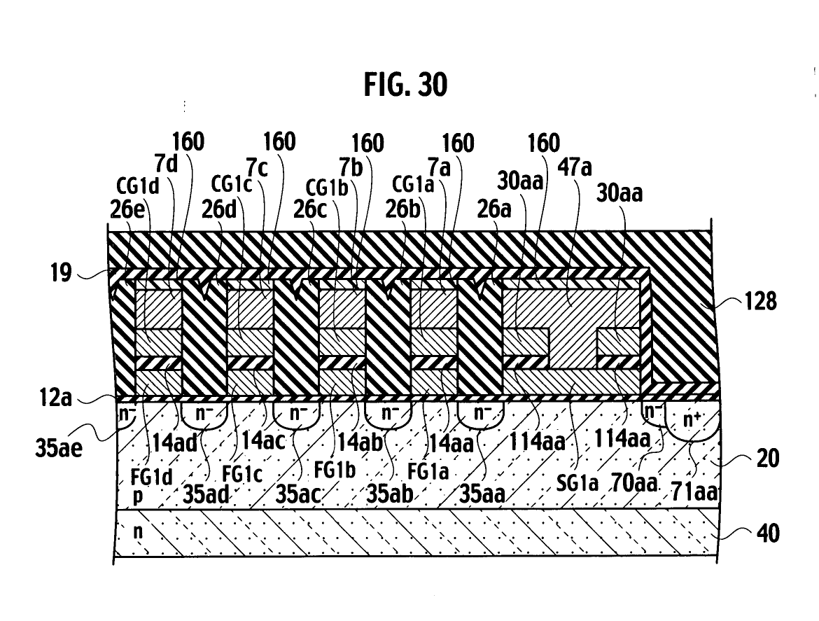

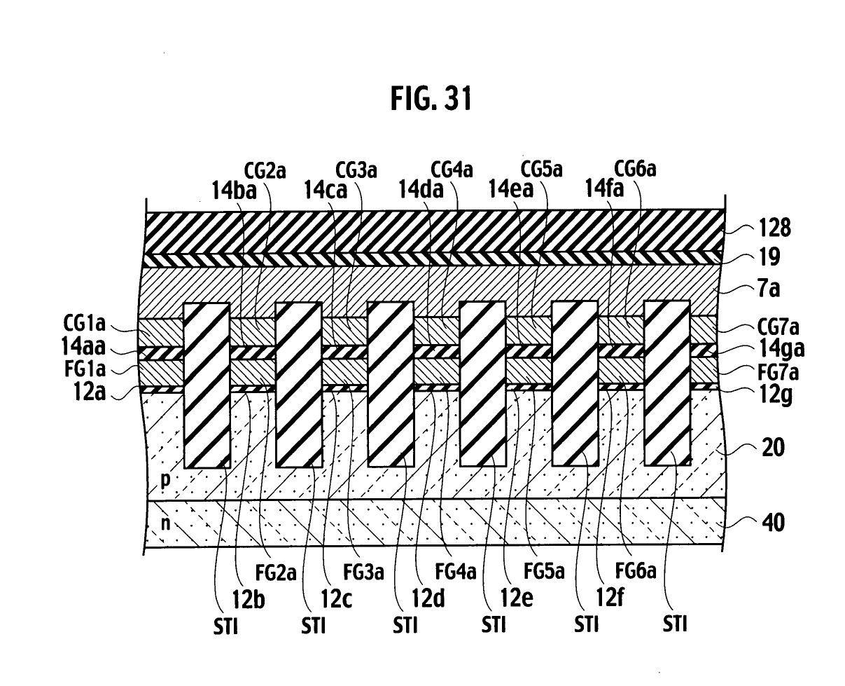

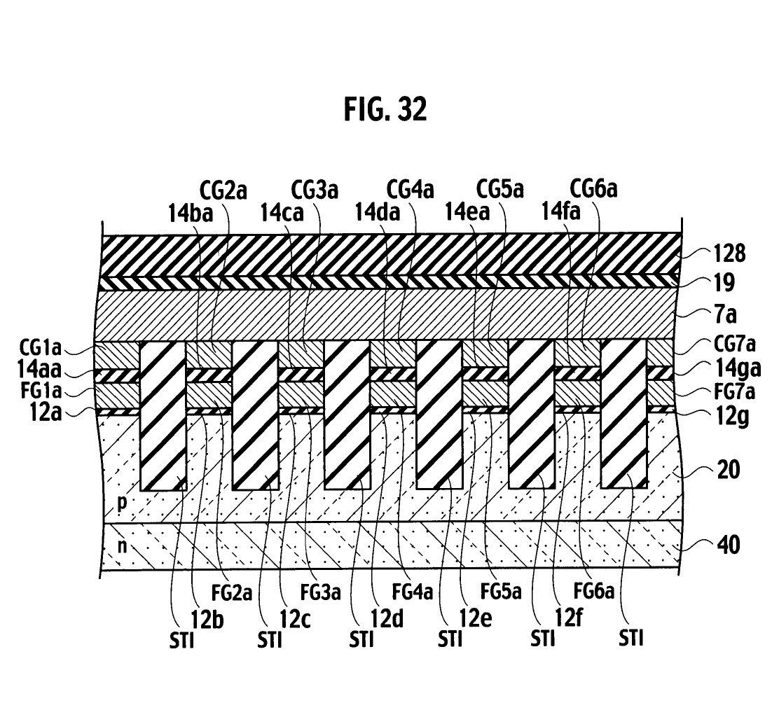

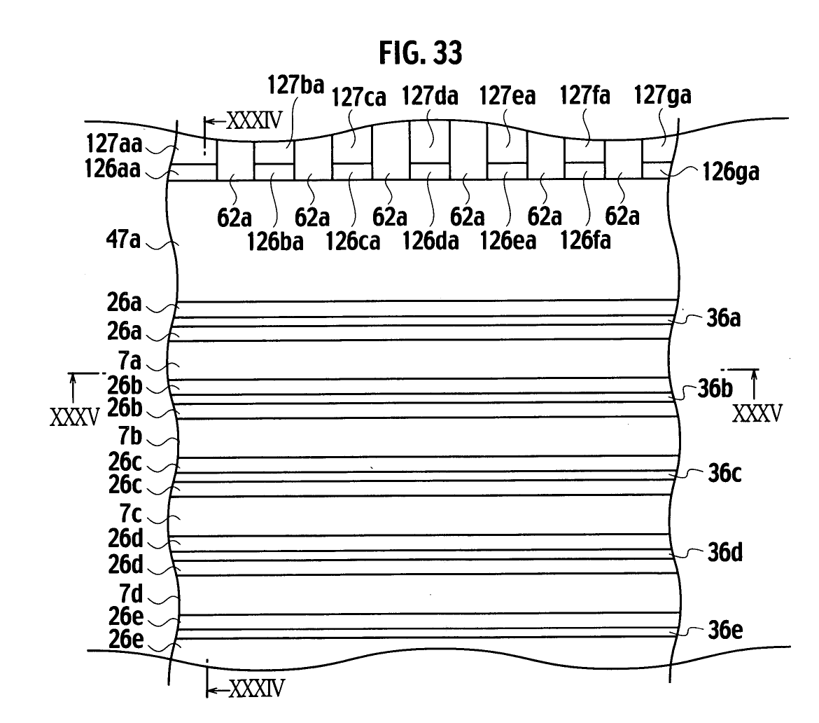

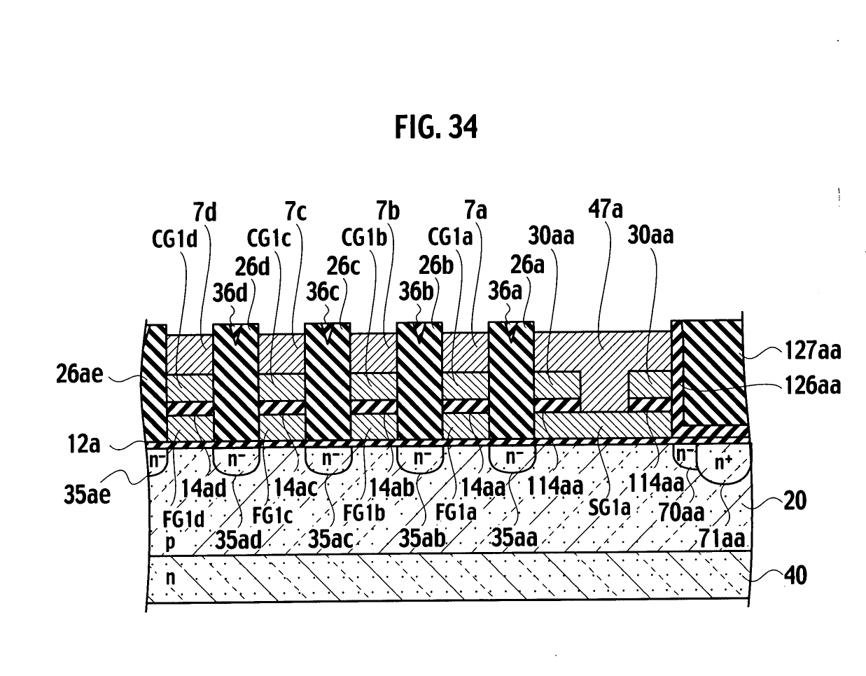

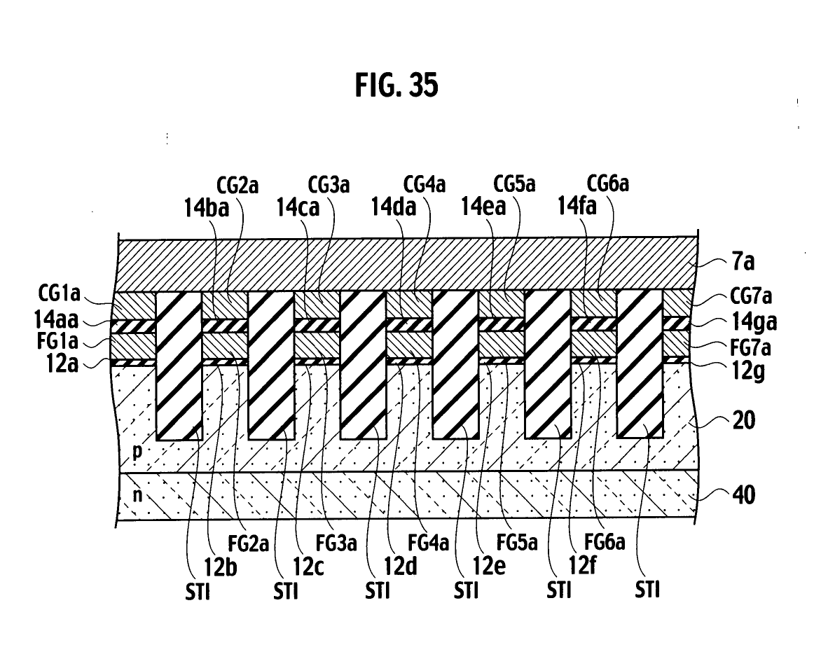

As shown in FIGS. 30 and 31, an insulator 19 of SiON or SiN and an insulator 128 of SiO₂ are deposited by the CVD process over the p-type semiconductor region 20. If the isolation insulators STIs are etched back in FIG. 13, FIG. 32 is an alternative to FIG. 31. Thereafter, the insulators 19, 128, and the etch mask 160 on the plurality of wiring portions 7a-7d, and 47a are stripped by the etch process. Consequently, as shown in FIG. 33, the sectional view of FIG. 34 taken on line XXXIV-XXXIV in FIG. 33, and the sectional view of FIG. 35 taken on line XXXV-XXXV in FIG. 33, the plurality of depressions in the sidewall insulators 26a, 26b, 26c, and 26d are filled with the plurality of insulators 36aa, 36ab, 36ac, and 36ad, respectively. Also, the sidewall insulator 126aa and a plurality of sidewall insulators 126ba, 126ca, 126da, 126ea, 126fa, and 126ga are formed along the lateral sidewall of the wiring portion 47a. And, the insulator 127aa and a plurality of insulators 127ba, 127ca, 127da, 127ea, 127fa, and 127ga are formed along the plurality of sidewall insulators 126aa-126ga.

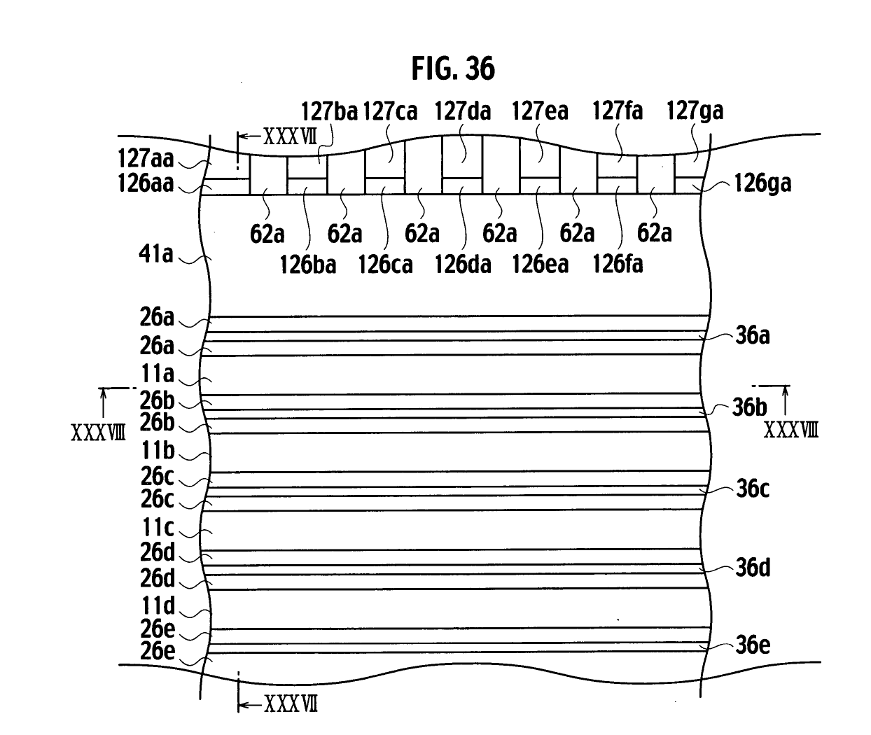

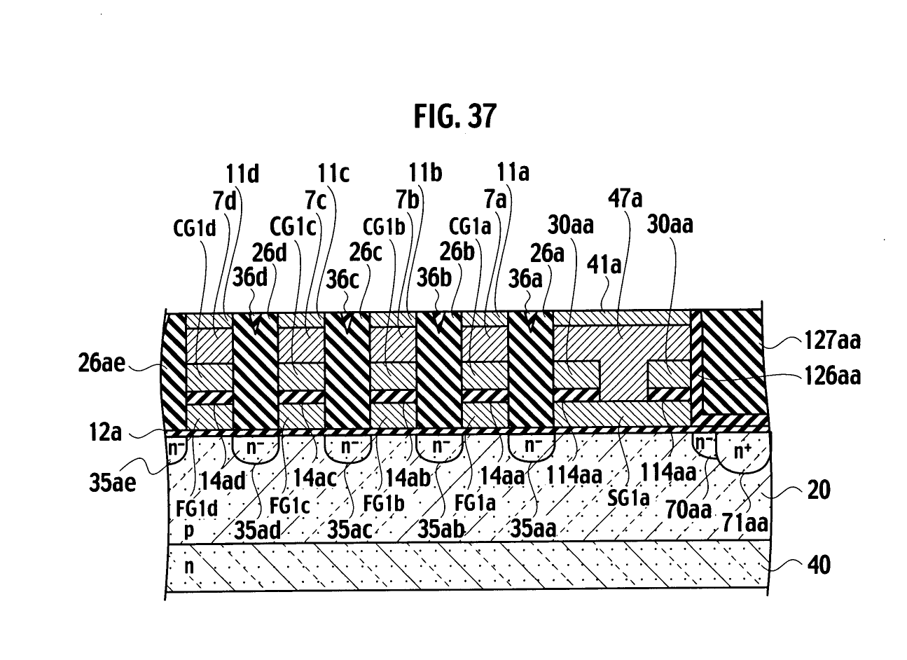

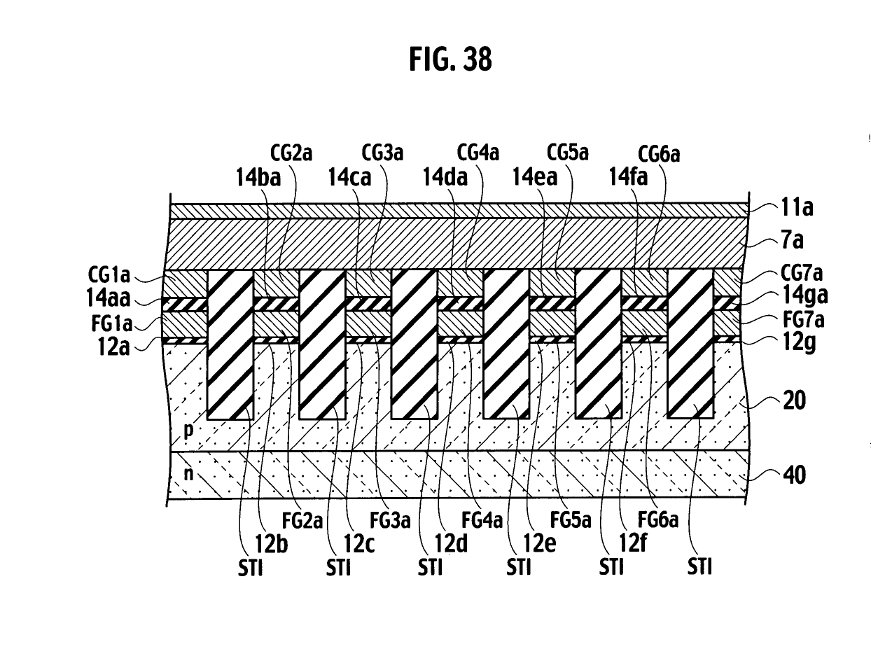

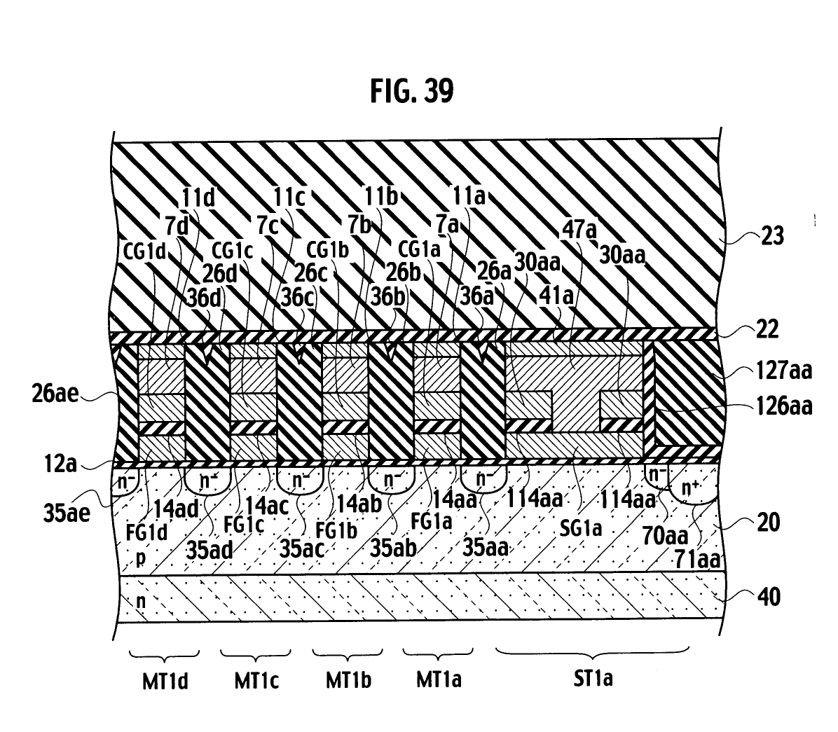

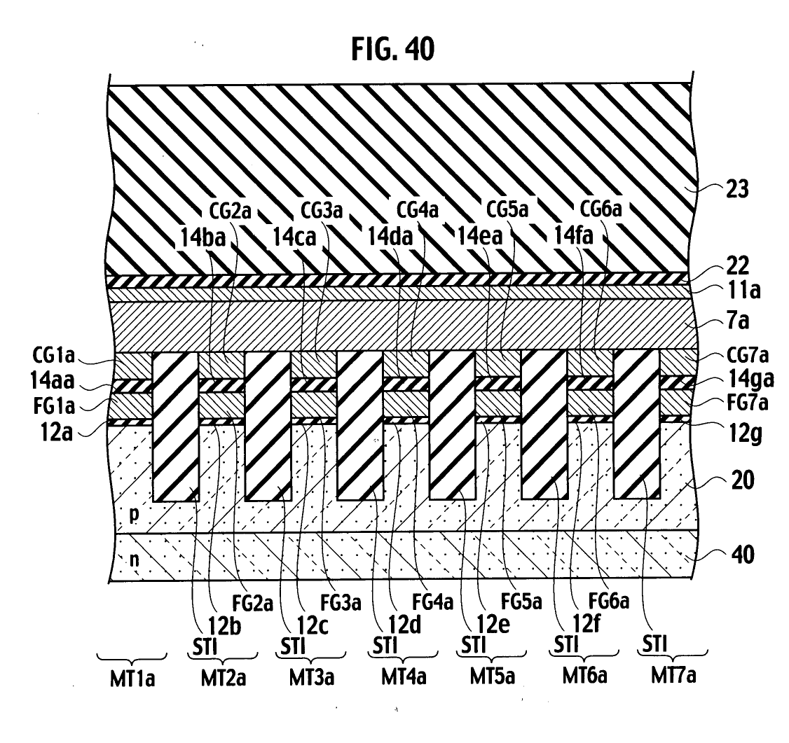

A refractory metal such as Ti and Co is deposited on the plurality of wiring portions 7a, 7b, 7c, 7d, and 47a and annealed to form the plurality of silicide layers 11a, 11b, 11c, 11d, and 41a as shown in FIG. 36, the sectional view of FIG. 37 taken on line XXXVII-XXXVII in FIG. 36, and the sectional view of FIG. 38 taken on line XXXVIII-XXXVIII in FIG. 36. After the excess refractory metal is removed by chemical etching process, the barrier insulator 22 composed of SiON and the interlevel insulator 23 composed of SiO₂ are deposited above the p-type semiconductor region 20, as shown in FIGS. 39 and 40, by the CVD process. Thereafter, a plurality of contact holes are delineated, Cu is deposited on the interlevel insulator 23 and polished by the CMP process. Consequently, the semiconductor memory shown in FIGS. 3 and 4 is obtained.

In the above described method, the plurality of column isolation trenches 51 shown in FIG. 10 are delineated after the first conducting layer 3, the interlayer insulator 4, and the second conducting layer 5, shown in FIG.8, are formed. Therefore, the isolation insulators STIs filled in the column isolation trenches 51 make it possible to isolate the plurality of inter-gate insulating layers 14aa-14ga in the plurality of memory cell transistors MT1a-MT7a as shown in FIG. 40.

### Other Embodiments

Although the invention has been described above by reference to the embodiment of the present invention, the present invention is not limited to the embodiment described above. Modifications and variations of the embodiment described above will occur to those skilled in the art, in light of the above teachings. For example, each structure of the plurality of inter-gate insulating layers 14aa-14ga, shown in FIG. 4, is not limited to a single layer. A multilayer structure is also possible for each of the inter-gate insulating layers 14aa-14ga. Also, the upper surfaces of the isolation insulators STIs and the plurality of control gate electrodes CG1a-CG7a are contiguous in FIG. 4. However, as long as the isolation insulators STIs electrically isolates the plurality of inter-gate insulating layers 14aa-14ga from each other, the upper surfaces of the isolation insulators STIs and the plurality of control gate electrodes CG1a-CG7a are not required to be contiguous. As described above, the present invention includes many variations of embodiments. Therefore, the scope of the invention is defined with reference to the following claims.

What is claimed is:

1. A semiconductor memory comprising:
a semiconductor region;
a plurality of floating gate electrodes arranged in a matrix on the semiconductor region through a tunnel insulating layer;
a plurality of inter-gate insulating layers disposed only on the plurality of floating gate electrodes, respectively;
a plurality of control gate electrodes disposed on the plurality of inter-gate insulating layers, respectively; and
a plurality of isolation insulators extending between a plurality of arrangements of the control gate electrodes along a column direction of the matrix, each of the isolation insulators penetrating into the semiconductor region so as to electrically isolate the plurality of inter-gate insulating layers from each other in the column direction.

2. The semiconductor memory of claim 1, further comprising a plurality of wiring portions running along a row direction of the matrix so as to share the control gate electrodes arranged along the row direction, each of the wiring portions electrically connecting the control gate electrodes in the row direction.

3. The semiconductor memory of claim 2, further comprising a plurality of silicide layers disposed on the wiring portions, respectively, each of the silicide layers electrically connected to corresponding one of the wiring portions.

4. The semiconductor memory of claim 3, further comprising a plurality of barrier insulators disposed on the silicide layers, respectively.

5. The semiconductor memory of claim 1, wherein each of the inter-gate insulating layers is composed of silicon dioxide.

6. The semiconductor memory of claim 1, wherein each of the inter-gate insulating layers is composed of silicon nitride.

7. The semiconductor memory of claim 1, wherein each of the inter-gate insulating layers is composed of alumina.

8. The semiconductor memory of claim 1, wherein each of the inter-gate insulating layers is composed of hafnium oxide.

9. The semiconductor memory of claim 1, wherein each of the inter-gate insulating layers is composed of zirconium oxide.

10. The semiconductor memory of claim 1, wherein each of the control gate electrodes is composed of titanium silicide.

11. The semiconductor memory of claim 1, wherein each of the control gate electrodes is composed of cobalt silicide.

12. The semiconductor memory of claim 1, wherein each of the control gate electrodes is composed of nickel silicide.

13. A method for manufacturing a semiconductor memory including:
forming a tunnel insulating layer on a semiconductor region;
depositing a first conducting layer on the tunnel insulating layer;
forming an interlayer insulator on the first conducting layer;
depositing a second conducting layer on the interlayer insulator;
delineating a plurality of column isolation trenches penetrating from the second conducting layer to an interior of the semiconductor region, the column isolation trenches extending in a column direction so as to divide the second conducting layer, the interlayer insulator, and the first conducting layer into a plurality of strips of the second conducting layers, the interlayer insulators, and the first conducting layers, respectively;
filling the plurality of column isolation trenches with a plurality of isolation insulators so that the plurality of strips of the interlayer insulators are isolated from each other in the column direction by the plurality of isolation insulators; and
dividing the stripes of the first conducting layers, the interlayer insulators, and the second conducting layers by a plurality of row isolation trenches running along a row direction perpendicular to the column direction to form a plurality of floating gate electrodes on the tunnel insulating layer, a plurality of inter-gate insulating layers on the plurality of floating gate electrodes, and a plurality of control gate electrodes on the plurality of inter-gate insulating layers, respectively.

14. The method of claim 13, further including:
forming a plurality of wiring portions extending in the row direction on the second conducting layer before dividing the strips of the first conducting layers, the interlayer insulators, and the second conducting layers.

15. The method of claim 14, further including:
depositing a silicide layer on the wiring portion.

16. The method of claim 13, wherein each of the inter-gate insulating layers is composed of silicon dioxide.

17. The method of claim 13, wherein each of the inter-gate insulating layers is composed of silicon nitride.

18. The method of claim 13, wherein each of the inter-gate insulating layers is composed of alumina.

19. The method of claim 13, wherein each of the inter-gate insulating layers is composed of hafnium oxide.

20. The method of claim 13, wherein each of the inter-gate insulating layers is composed of zirconium oxide.
